(19) United States
(12) Patent Application Publication
(10) Pub. No.: US 2019/0312043 A1
(43) Pub. Date: Oct. 10, 2019

(54) METHOD OF MANUFACTURING SEMICONDUCTOR DEVICE

(71) Applicant: RENESAS ELECTRONICS CORPORATION, Tokyo (JP)

(72) Inventor: Tatsuyoshi MIHARA, Tokyo (JP)

(21) Appl. No.: 16/362,064

(22) Filed: Mar. 22, 2019

(30) Foreign Application Priority Data
Apr. 9, 2018 (JP) 2018-074433

(51) Int. Cl. H01L 27/1157; H01L 27/11565; H01L 21/311; H01L 21/3105; H01L 21/02; H01L 21/28; H01L 29/792; H01L 29/78

(52) U.S. Cl. CPC H01L 27/1157; H01L 27/11565; H01L 21/31116; H01L 21/31051; H01L 29/7851; H01L 21/28088; H01L 21/28282; H01L 29/792; H01L 21/02178

(57) ABSTRACT

Provided is an inexpensive high-performance split gate MONOS memory. In a manufacturing process of a split gate MONOS memory, a protective layer is formed in an upper part of a control gate electrode before metal substitution of a memory gate electrode.

### CROSS-REFERENCE TO RELATED APPLICATIONS

The disclosure of Japanese Patent Application No. 2018-074433 filed on Apr. 9, 2018 including the specification, drawings and abstract is incorporated herein by reference in its entirety.

### BACKGROUND

The present invention relates to a structure of a semiconductor device and a method for producing the structure. Specifically, the invention relates to a technique effective in use for a semiconductor device having a split-gate nonvolatile memory.

An electrically erasable and programmable read only memory (EEPROM) is widely used as an electrically writable and erasable, nonvolatile semiconductor storage device. Such a storage device typified by a flash memory has a region storing charges in a gate insulating film of MISFET, and stores data using a nonvolatile change in threshold voltage due to the region. In addition, the storage device determines a threshold voltage from a channel current value of the MISFET to perform readout. Charges are stored by use of a floating gate electrode surrounded by an insulating film or of a trap level in the insulating film.

Such a flash memory includes a split gate (SG) cell using a metal-oxide-nitride-oxide-semiconductor (MONOS) film. The split gate MONOS is characterized by achieving high charge retention properties (reliability) by trapping charges in a silicon nitride film (SiN film) in the MONOS film of a memory gate MOS (MG-MOS), and high speed, low power consumption readout due to a thin-film gate oxide film used for a control gate.

In a control gate MOS (CG-MOS) of the split gate MONOS (SG-MONOS), a high dielectric constant film (High-K film) is used in place of a thin-film gate oxide film (SiO₂ film) to form a High-k metal gate MOS (HKMG-MOS), making it possible to extremely improve performance of CG-MOS.

A side surface of the gate electrode of the control gate MOS (CG-MOS) is covered with a silicon nitride film (SiN film), which advantageously suppress deterioration in performance of the High-K film, prevents formation of metal silicide in a surface of a polysilicon film of MG of the gate electrode of the memory gate MOS (MG-MOS), and eliminates a fear of reduction in yield by scratch or the like during CMP polishing that exposes the gate electrode surface. Furthermore, a metal silicide film is reformed on the MG surface after the polysilicon film surface is exposed, which reduces resistance of the MG electrode.

The background art of the technical field of the invention includes, for example, a technique described in Japanese Unexamined Patent Application Publication No. 2017-168571. Japanese Unexamined Patent Application Publication No. 2017-168571 discloses a SG-MONOS structure having CG-MOS of HKMG-MOS and MG-MOS including a polysilicon film, and describes a technique in which MG-MOS first is used in a process to increase a process margin in removing a dummy CG electrode, and a material of the dummy CG electrode is changed from the polysilicon film to another material to provide etching selectivity to the polysilicon film of the MG electrode during removal of the dummy CG electrode.

Japanese Unexamined Patent Application Publication Nos. 2015-162621, 2015-103698, 2016-51735, and 2012-248652 each disclose a technique in which a metal gate is used in CG-MOS, and a polysilicon film or a stacked structure of a polysilicon film and a metal film is used in MG-MOS.

### SUMMARY

In the related art, a memory gate MOS (MG-MOS) with no use of metal gate involves a fear of an obvious variation in characteristics or an increase in MG resistance associated with size reduction of the MG-MOS. When metal substitution of a polysilicon film as a gate electrode of the MG-MOS is intended as a countermeasure, the metal film as the gate electrode of the CG-MOS must be protected during the metal substitution.

However, for example, when a material (silicon oxide film) different from the polysilicon film is used to selectively remove the dummy CG electrode, two more masks are necessary because the polysilicon film in a logic circuit and the dummy CG electrode are removed in separate steps, which is costly disadvantage.

Other objects and novel features will be clarified from the description of this specification and the accompanying drawings.

According to one embodiment of the present disclosure, a protective layer is formed in an upper part of a control gate electrode before metal substitution of the memory gate electrode in a manufacturing process of the split gate MONOS memory.

According to the one embodiment, a metal gate electrode can be used for both the control gate electrode and the memory gate electrode without increasing the number of steps more than necessary.

This achieves an inexpensive and high-performance split gate MONOS memory and a method of manufacturing the split gate MONOS memory.

### BRIEF DESCRIPTION OF THE DRAWINGS

FIG. 1 is a sectional view illustrating part of a semiconductor device according to one embodiment of the invention.

FIG. 2 is a sectional view illustrating part of a semiconductor device of a comparative example.

FIG. 3A is a plan view illustrating part of the semiconductor device of the one embodiment of the invention.

FIG. 3B is a perspective view illustrating part of the semiconductor device of the one embodiment of the invention.

FIG. 3C is a sectional view along a line A-A′ in FIG. 3A.

FIG. 4 is a sectional view illustrating a manufacturing process of the semiconductor device of the one embodiment (first example) of the invention.

FIG. 5 is a sectional view illustrating the manufacturing process of the semiconductor device following FIG. 4.

FIG. 6 is a sectional view illustrating the manufacturing process of the semiconductor device following FIG. 5.

FIG. 7 is a sectional view illustrating the manufacturing process of the semiconductor device following FIG. 6.

FIG. 8 is a sectional view illustrating the manufacturing process of the semiconductor device following FIG. 7.

FIG. 9 is a sectional view illustrating the manufacturing process of the semiconductor device following FIG. 8.

FIG. 10 is a sectional view illustrating the manufacturing process of the semiconductor device following FIG. 9.

FIG. 11 is a sectional view illustrating the manufacturing process of the semiconductor device following FIG. 10.

FIG. 12 is a sectional view illustrating the manufacturing process of the semiconductor device following FIG. 11.

FIG. 13 is a sectional view illustrating the manufacturing process of the semiconductor device following FIG. 12.

FIG. 14 is a sectional view illustrating the manufacturing process of the semiconductor device following FIG. 13.

FIG. 15 is a sectional view illustrating the manufacturing process of the semiconductor device following FIG. 14.

FIG. 16 is a sectional view illustrating the manufacturing process of the semiconductor device following FIG. 15.

FIG. 17 is a sectional view illustrating the manufacturing process of the semiconductor device following FIG. 16.

FIG. 18 is a sectional view illustrating the manufacturing process of the semiconductor device following FIG. 17.

FIG. 19 is a sectional view illustrating the manufacturing process of the semiconductor device following FIG. 18.

FIG. 20 is a sectional view illustrating a manufacturing process of a semiconductor device of one embodiment (second example) of the invention.

FIG. 21 is a sectional view illustrating the manufacturing process of the semiconductor device following FIG. 20.

FIG. 22 is a sectional view illustrating the manufacturing process of the semiconductor device following FIG. 21.

FIG. 23 is a sectional view illustrating the manufacturing process of the semiconductor device following FIG. 22.

FIG. 24 is a sectional view illustrating the manufacturing process of the semiconductor device following FIG. 23.

FIG. 25 is a sectional view illustrating the manufacturing process of the semiconductor device following FIG. 24.

FIG. 26 is a sectional view illustrating the manufacturing process of the semiconductor device following FIG. 25.

FIG. 27 is a sectional view illustrating the manufacturing process of the semiconductor device following FIG. 26.

FIG. 28 is a sectional view illustrating the manufacturing process of the semiconductor device following FIG. 27.

FIG. 29 is a sectional view illustrating the manufacturing process of the semiconductor device following FIG. 28.

FIG. 30 is a sectional view illustrating the manufacturing process of the semiconductor device following FIG. 29.

FIG. 31 is a sectional view illustrating the manufacturing process of the semiconductor device following FIG. 30.

FIG. 32 is a sectional view illustrating the manufacturing process of the semiconductor device following FIG. 31.

FIG. 33 is a sectional view illustrating the manufacturing process of the semiconductor device following FIG. 32.

FIG. 34 is a sectional view illustrating the manufacturing process of the semiconductor device following FIG. 33.

FIG. 35 is a sectional view illustrating the manufacturing process of the semiconductor device following FIG. 34.

FIG. 36 is a sectional view illustrating a manufacturing process of a semiconductor device of one embodiment (third example) of the invention.

FIG. 37 is a sectional view illustrating the manufacturing process of the semiconductor device following FIG. 36.

FIG. 38 is a sectional view illustrating the manufacturing process of the semiconductor device following FIG. 37.

FIG. 39 is a sectional view illustrating the manufacturing process of the semiconductor device following FIG. 38.

FIG. 40 is a sectional view illustrating the manufacturing process of the semiconductor device following FIG. 39.

FIG. 41 is a sectional view illustrating the manufacturing process of the semiconductor device following FIG. 40.

FIG. 42 is a sectional view illustrating the manufacturing process of the semiconductor device following FIG. 41.

FIG. 43 is a sectional view illustrating the manufacturing process of the semiconductor device following FIG. 42.

FIG. 44 is a sectional view illustrating the manufacturing process of the semiconductor device following FIG. 43.

FIG. 45 is a sectional view illustrating the manufacturing process of the semiconductor device following FIG. 44.

FIG. 46 is a sectional view illustrating the manufacturing process of the semiconductor device following FIG. 45.

FIG. 47 is a sectional view illustrating the manufacturing process of the semiconductor device following FIG. 46.

FIG. 48 is a sectional view illustrating the manufacturing process of the semiconductor device following FIG. 47.

FIG. 49 is a sectional view illustrating the manufacturing process of the semiconductor device following FIG. 48.

FIG. 50 is a sectional view illustrating the manufacturing process of the semiconductor device following FIG. 49.

FIG. 51 is a sectional view illustrating the manufacturing process of the semiconductor device following FIG. 50.

FIG. 52 is a sectional view illustrating a manufacturing process of a semiconductor device of one embodiment (forth example) of the invention.

FIG. 53 is a sectional view illustrating the manufacturing process of the semiconductor device following FIG. 52.

FIG. 54 is a sectional view illustrating the manufacturing process of the semiconductor device following FIG. 53.

FIG. 55 is a sectional view illustrating the manufacturing process of the semiconductor device following FIG. 54.

FIG. 56 is a sectional view illustrating the manufacturing process of the semiconductor device following FIG. 55.

FIG. 57 is a sectional view illustrating the manufacturing process of the semiconductor device following FIG. 56.

FIG. 58 is a sectional view illustrating the manufacturing process of the semiconductor device following FIG. 57.

FIG. 59 is a sectional view illustrating the manufacturing process of the semiconductor device following FIG. 58.

FIG. 60 is a sectional view illustrating the manufacturing process of the semiconductor device following FIG. 59.

FIG. 61 is a sectional view illustrating the manufacturing process of the semiconductor device following FIG. 60.

FIG. 62 is a sectional view illustrating the manufacturing process of the semiconductor device following FIG. 61.

FIG. 63 is a sectional view illustrating the manufacturing process of the semiconductor device following FIG. 62.

FIG. 64 is a sectional view illustrating the manufacturing process of the semiconductor device following FIG. 63.

FIG. 65 is a sectional view illustrating the manufacturing process of the semiconductor device following FIG. 64.

FIG. 66 is a sectional view illustrating the manufacturing process of the semiconductor device following FIG. 65.

FIG. 67 is a sectional view illustrating the manufacturing process of the semiconductor device following FIG. 66.

### DETAILED DESCRIPTION

Hereinafter, some examples are described with reference to the accompanying drawings. The same components in the drawings are designated by the same numeral, and duplicated description is omitted.

### FIRST EXAMPLE

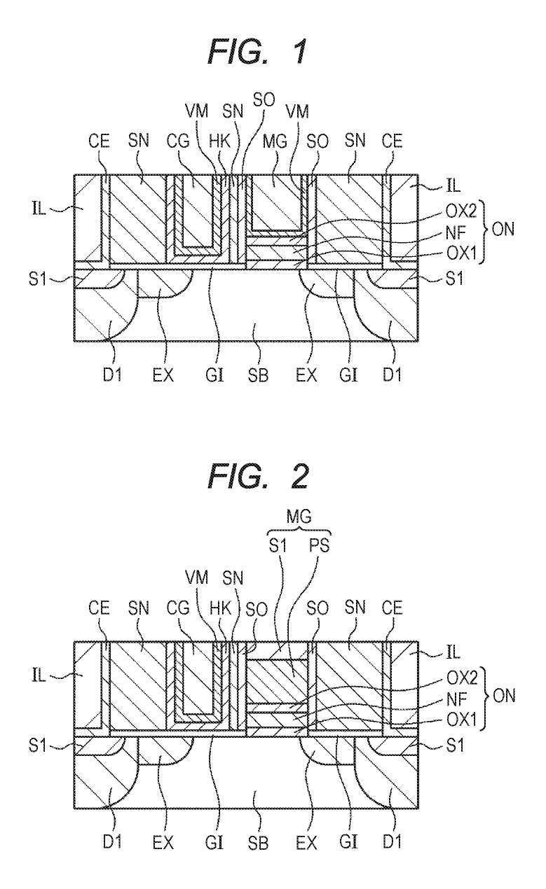

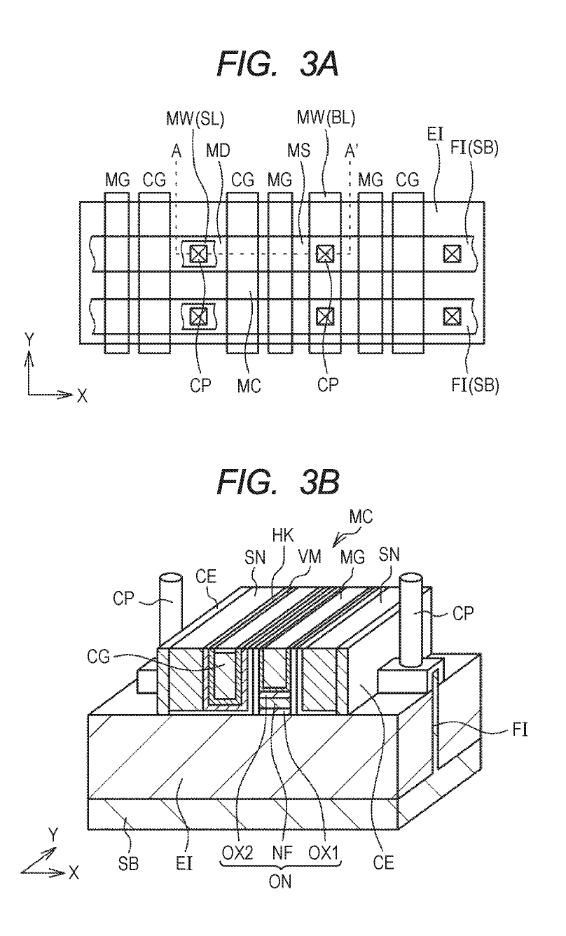

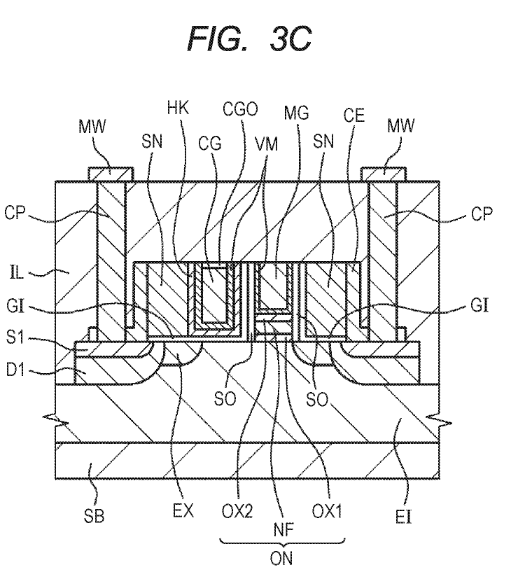

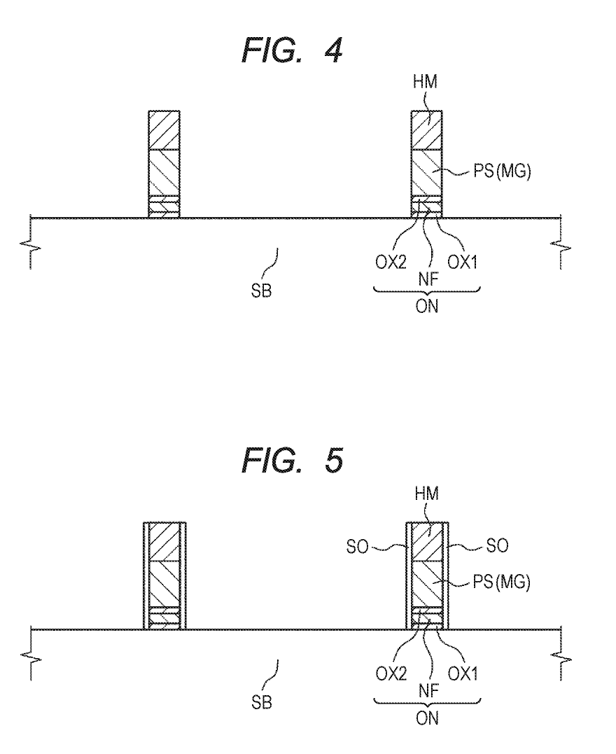

A structure of a semiconductor device of a first example and a method of manufacturing the semiconductor device are now described with reference to FIGS. 1 to 19. FIG. 1 illustrates a cross section of a major part of the semiconductor device of the first example. FIG. 2 illustrates a comparative example shown in comparison with FIG. 1 for better understanding of the configuration of FIG. 1. FIGS. 3A to 3C are views of the major part of the semiconductor device of the first example as viewed from different directions, showing an example where a split gate MONOS (SG-MONOS) of the first example is applied to a fin field effect transistor (Fin-FET). FIGS. 4 to 19 are sectional views of steps of a method for manufacturing the semiconductor device (SG-MONOS) of the first example shown in FIG. 1.

### Structure of Semiconductor Device of Comparative Example

A memory cell structure of the semiconductor device (SG-MONOS) of the comparative example is now described with reference to FIG. 2. FIG. 2 shows the major part of the structure in a simplified manner for better understanding while omitting a contact plug (via) CP and an interconnection MW as described later.

As shown in FIG. 2, a semiconductor substrate SB has a memory cell of a nonvolatile memory including a memory transistor and a control transistor. While not shown, the memory cell includes a plurality of memory cells formed in an array on the semiconductor substrate SB.

As shown in FIG. 2, the memory cell of the nonvolatile memory of the semiconductor device of the comparative example is a split gate (SG) memory cell including two MISFETs: a control transistor having a control gate electrode CG and a memory transistor having a memory gate electrode MG coupled to each other.

A MISFET having a gate insulating film including a charge storage part and a memory gate electrode MG is referred to as memory transistor, and a MISFET having a gate insulating film and a control gate electrode CG is referred to as control transistor. Hence, the memory gate electrode MG is a gate electrode of the memory transistor, and the control gate electrode CG is a gate electrode of the control transistor. The control gate electrode CG and the memory gate electrode MG are gate electrodes to configure the memory cell of the nonvolatile memory. The control transistor may be referred to as selection transistor because it acts as a memory cell selection transistor.

A configuration of the memory cell of the semiconductor device of the comparative example is specifically described below.

As shown in FIG. 2, the memory cell of the nonvolatile memory includes n-type semiconductor regions (each including a diffusion region D1 and an extension region EX) for a source and a drain formed in a p-type well of the semiconductor substrate SB, the memory gate electrode MG formed on the semiconductor substrate SB (p-type well), and the control gate electrode CG formed adjacent to the memory gate electrode MG on the semiconductor substrate SB (p-type well). The memory cell further includes an insulating film (ONO film ON) formed between the memory gate electrode MG and the semiconductor substrate SB (p-type well), and an insulating film (High-k film HK) formed between the control gate electrode CG and the semiconductor substrate SB (p-type well).

The control gate electrode CG and the memory gate electrode MG extend along the main surface of the semiconductor substrate SB and are arranged side by side while a sidewall insulating film (sidewall SO), an insulating film (silicon nitride film SN), and the insulating film (High-k film HK) are provided between the opposed side surfaces of the gate electrodes CG and MG. The control gate electrode CG and the memory gate electrode MG are formed on the semiconductor substrate SB (p-type well) between the semiconductor regions (diffusion regions D1 and extension regions EX) for the source and the drain. In FIG. 2, the memory gate electrode MG is located on the right semiconductor region (source region MS) side, and the control gate electrode CG is located on the left semiconductor region (drain region MD) side.

The insulating film (ONO film ON) including a stacked film of a silicon oxide film OX1, a silicon nitride film NF, and a silicon oxide film OX2 in ascending order is provided between the memory gate electrode MG and the semiconductor substrate SB (p-type well). The insulating film (High-k film HK) between the control gate electrode CG and the semiconductor substrate SB (p-type well) is also formed at a position adjacent to each side surface of the control gate electrode CG in addition to a position adjacent to the lower surface of the control gate electrode CG. That is, the High-k film HK continuously extends over between the control gate electrode CG and the semiconductor substrate SB (p-type well), between the control gate electrode CG and the memory gate electrode MG, and between the control gate electrode CG and the silicon nitride film SN.

The memory gate electrode MG and the control gate electrode CG are adjacent to each other via the sidewall insulating film (sidewall SO), the insulating film (silicon nitride film SN), and the insulating film (High-k film HK). That is, the stacked film of the sidewall SO, the silicon nitride film SN, and the High-k film HK is provided between the memory gate electrode MG and the control gate electrode CG.

There are provided between the memory gate electrode MG and the control gate electrode CG: the sidewall insulating film (sidewall SO) adjacent to the memory gate electrode MG; the insulating film (High-k film HK) adjacent to the control gate electrode CG via a Vth control metal film VM; and the insulating film (silicon nitride film SN) between the sidewall insulating film (sidewall SO) and the insulating film (High-k film HK). That is, the sidewall SO, the silicon nitride film SN, and the High-k film HK are arranged in this order between the memory gate electrode MG and the control gate electrode CG in a direction from the memory gate electrode MG to the control gate electrode CG.

The sidewall insulating film (sidewall SO) includes, for example, a silicon oxynitride film (SiON film), and the High-k film HK includes a high-dielectric-constant insulating film. The High-k film HK is an insulating material film having a higher dielectric constant than the silicon nitride film (SiN film). In this application, a High-k film, a high-dielectric-constant film, a high-dielectric-constant insulating film, or a high-dielectric-constant gate insulating film refers to a film having a higher dielectric constant (specific inductive capacity) than the silicon nitride film (SiN film).

A metal oxide film such as a hafnium oxide film, a zirconium oxide film, an aluminum oxide film, a tantalum oxide film or a lanthanum oxide film may be used as the High-k film HK. Such a metal oxide film may contain one or both of nitrogen (N) and silicon (Si). The High-k film HK is therefore an insulating film containing a metal element and oxygen (O) as constituent elements.

The High-k film HK can be formed by, for example, an atomic layer deposition process or a CVD process. The High-k film HK is formed to a thickness of about 1 to 3 nm, for example. When the high dielectric constant film (High-K film herein) is used as the gate insulating film, since physical thickness of the gate insulating film can be increased compared with a case where a silicon oxide film is used as the gate insulating film, the amount of leakage current can be advantageously reduced.

The silicon nitride film NF in the ONO film ON is an insulating film for storing charges, and serves as a charge storage part (charge storage layer). That is, the silicon nitride film NF is a trapping insulating film formed in the ONO film ON. The ONO film ON therefore can be considered as an insulating film internally having the charge storage part.

The diffusion region D1 and the extension region EX are semiconductor regions for a source or a drain. Specifically, in FIG. 2, a first pair of the diffusion region D1 and the extension region EX are semiconductor regions collectively serving as one of the source and drain regions, while a second pair of the diffusion region D1 and the extension region EX are semiconductor regions collectively serving as the other of the source and drain regions.

The source and drain regions of the comparative example shown in FIG. 2 each include a semiconductor region containing an n-type impurity introduced therein and have an LDD structure. The source and drain semiconductor regions each have an n⁻-type semiconductor region (extension region EX) and an n⁺-type semiconductor region (diffusion region DX) having a higher impurity concentration than the n⁻-type semiconductor region.

The diffusion region D1 and the extension region EX are collectively formed on the semiconductor substrate SB at a position adjacent to the memory gate electrode MG in a gate length direction (of the memory gate electrode MG), and on the semiconductor substrate SB at a position adjacent to the control gate electrode CG in a gate length direction (of the control gate electrode CG).

A sidewall (sidewall spacer) SO including an insulator (insulating film) is formed on a sidewall of the memory gate electrode MG on a side opposite to the side adjacent to the control gate electrode CG. Although the sidewall (sidewall spacer) SO is also formed at a position adjacent to the control gate electrode CG, the High-k film HK and the Vth control metal film VM are provided between the sidewall (sidewall spacer) SO and the control gate electrode CG.

A gate insulating film GI is provided between the silicon nitride film SN and the semiconductor substrate SB. Although the silicon nitride film SN is formed at a position adjacent to the memory gate electrode MG, the sidewall insulating film (sidewall SO) is provided between the silicon nitride film SN and the memory gate electrode MG, and the gate insulating film GI is provided between the silicon nitride film SN and the semiconductor substrate SB. Although the silicon nitride film SN is also formed at a position adjacent to the control gate electrode CG, the Vth control metal film VM and the High-k film HK are provided between the silicon nitride film SN and the control gate electrode CG, and the gate insulating film GI is also provided between the silicon nitride film SN and the semiconductor substrate SB.

An interlayer insulating film IL is formed on a side, opposite to the side adjacent to the memory gate electrode MG, of the silicon nitride film SN via a silicon nitride film CE. The interlayer insulating film IL is also formed on a side, opposite to the side adjacent to the control gate electrode CG, of the silicon nitride film SN via a silicon nitride film CE. The silicon nitride film CE is also provided between the interlayer insulating film IL and the semiconductor substrate SB. The silicon nitride film CE between the silicon nitride film SN and the interlayer insulating film IL is formed integrally with the silicon nitride film CE between the interlayer insulating film IL and the semiconductor substrate SB.

In FIG. 2, a first n⁻-type semiconductor region (extension region EX) (right EX in FIG. 2) to configure the source/drain region is formed below the sidewall spacer SO. Similarly, a first n⁺-type semiconductor region (diffusion region D1) (right D1 in FIG. 2) to configure the source/drain region is formed on an outer side of the first n⁻-type semiconductor region (extension region EX). Hence, the low-concentration n⁻-type semiconductor region (extension region EX) is formed so as to be adjacent to the channel region of the memory transistor (MG-MOS). The high-concentration n⁺-type semiconductor region (diffusion region D1) is formed adjacent to the low-concentration n⁻-type semiconductor region (extension region EX), and away from the channel region of the memory transistor (MG-MOS) by a distance corresponding to the n⁻-type semiconductor region (extension region EX).

On the other hand, a second n⁻-type semiconductor region (extension region EX) (left EX in FIG. 2) to configure the source/drain region is formed below the silicon nitride film SN. Similarly, a second n⁺-type semiconductor region (diffusion region D1) (left D1 in FIG. 2) to configure the source/drain region is formed on an outer side of the second n⁻-type semiconductor region (extension region EX). Hence, the low-concentration n⁻-type semiconductor region (extension region EX) is formed so as to be adjacent to the channel region of the control transistor (CG-MOS). The high-concentration n⁺-type semiconductor region (diffusion region D1) is formed adjacent to the low-concentration n⁻-type semiconductor region (extension region EX), and away from the channel region of the control transistor (CG-MOS) by a distance corresponding to the n⁻-type semiconductor region (extension region EX).

The channel region of the memory transistor is formed below the insulating film (ONO film ON) under the memory gate electrode MG. The channel region of the control transistor is formed below the insulating film (High-k film HK) below the control gate electrode CG.

A portion of the High-k film HK lying between the control gate electrode CG and the semiconductor substrate SB, i.e., lying below the control gate electrode CG, serves as a gate insulating film of the control transistor. The insulating film (ONO film ON) lying between the memory gate electrode MG and the semiconductor substrate SB, i.e., lying under the memory gate electrode MG, serves as a gate insulating film (gate insulating film internally having a charge storage part) of the memory transistor. The sidewall spacer SO, the silicon nitride film SN, and the High-k film HK provided between the memory gate electrode MG and the control gate electrode CG collectively serve as an insulating film to insulate (electrically isolate) between the memory gate electrode MG and the control gate electrode CG.

A metal silicide layer S1 is formed in the upper part of each of the left and right n⁺-type semiconductor regions (diffusion regions D1). The memory gate electrode MG, including a polysilicon film PS, is a so-called silicon gate electrode. The metal silicide layer S1 is also formed in the upper part of the memory gate electrode MG. The control gate electrode CG, including a metal film (conductive film exhibiting metallic conduction), is a so-called metal gate electrode.

### Structure of Semiconductor Device of First Example

A memory cell structure of the semiconductor device (SG-MONOS) of the first example is now described with reference to FIG. 1. As with the comparative example of FIG. 2, FIG. 1 shows the major part of the structure in a simplified manner for better understanding while omitting the contact plugs (vias) CP and the interconnection MW as described later.

While the comparative example of FIG. 2 uses the silicon gate electrode including the polysilicon film PS and the metal silicide layer S1 as the memory gate electrode MG, the semiconductor device (SG-MONOS) of the first example uses the metal gate electrode including the metal film (conductive film exhibiting metallic conduction) as the memory gate electrode MG.

A metal material such as, for example, aluminum (Al) or tungsten (W) is used for the metal film of the memory gate electrode MG. The Vth control metal film VM is provided between the metal film of the memory gate electrode MG and the surrounding insulating film (including the sidewall spacers SO on both sides and the underlying silicon oxide film OX2 in FIG. 1).

The memory cell structure of the semiconductor device (SG-MONOS) of the first example shown in FIG. 1 is the same as the memory cell structure of the described comparative example of FIG. 2 except that the metal gate electrode including the metal film (conductive film exhibiting metallic conduction) is used as the memory gate electrode MG, and thus duplicated description is omitted.

The memory cell structure of the semiconductor device (SG-MONOS) of the first example shown in FIG. 1 uses the metal gate electrode including the metal film (conductive film exhibiting metallic conduction) as the memory gate electrode MG, making it possible to suppress a variation in characteristics or an increase in resistance of the memory gate electrode MG (MG-MOS) associated with scaling (reduction in cell size) even if the memory cell structure is scaled.

### Application to Fin Field Effect Transistor (Fin-FET)

An example of application of the split gate MONOS (SG-MONOS) of the first example to a fin field effect transistor (Fin-FET) is now described with reference to FIGS. 3A to 3C.

FIG. 3A is a plan view illustrating a memory cell array in the case where the split gate MONOS (SG-MONOS) of the first example is applied to the fin field effect transistor (Fin-FET). Hereinafter, a region in which the memory cell is formed is referred to as memory cell region. In the memory cell region, a plurality of fins FI extending in an X direction are arranged in a Y direction at a predetermined interval. The X and Y directions are each along the main surface of the semiconductor substrate SB while being orthogonal to each other.

As shown in FIG. 3A, a plurality of control gate electrodes CG and a plurality of memory gate electrodes MG are disposed on the fins FI while extending in the Y direction. The drain region MD on a control gate electrode CG side and the source region MS on a memory gate electrode side are formed in the upper surface of each fin FI so as to sandwich the control gate electrode CG and the memory gate electrode MG. That is, one control gate electrode CG and one memory gate electrode MG adjacent to each other are located between the source region MS and the drain region MD in the X direction.

The drain region MD and the source region MS are each an n-type semiconductor region. The drain region MD is formed between two control gate electrodes CG adjacent to each other in the X direction, and the source region MS is formed between two memory gate electrodes MG adjacent to each other in the X direction. The memory cell MC is a nonvolatile memory element configured by the control gate electrode CG, the memory gate electrode MG, the drain region MD, and the source region MS. Hereinafter, the source region MS and the drain region MD configuring one memory cell may be referred to as source-drain region.

Two memory cells MC adjacent to each other in the X direction share the drain region MD or the source region MS. The two memory cells MC sharing the drain region MD are line-symmetric in the X direction with the drain region MD extending in the Y direction as an axis. The two memory cells MC sharing the source region MS are line-symmetric in the X direction with respect to the source region MS extending in the Y direction.

A plurality of memory cells MC are formed on each fin FI while being arranged in the X direction. The drain region

MD of each memory cell MC is electrically coupled to a source line SL including the interconnection MW extending in the X direction via the contact plug (via) CP formed in a contact hole penetrating an undepicted interlayer insulating film formed on the memory cell MC. The source region MS of each of the memory cells MC arranged in the Y direction is electrically coupled to a bit line BL including the interconnection MW extending in the Y direction.

The fin FI includes a projecting semiconductor layer having a roughly rectangular parallelepipedal shape, which projects from the main surface of the semiconductor substrate SB in a direction perpendicular to the main surface. The fin FI need not necessarily have the rectangular parallelepipedal shape, and may have a rounded corner of a rectangle in a sectional view in the short side direction. Each side surface of the fin FI may be perpendicular to the main surface of the semiconductor substrate SB, or may be slightly inclined at an angle close to the perpendicular angle. That is, each sectional shape of the fin FI is a roughly rectangle or a trapezoid.

As shown in the plan view of the semiconductor substrate SB of FIG. 3A, an extending direction of the fin FI corresponds to a long side direction of each fin, and a direction orthogonal to the long side direction corresponds to a short side direction of the fin. That is, the fin has a length larger than a width. The fin FI may have any shape as long as the fin FI includes a projecting semiconductor layer having a length, a width, and a height. For example, the fin FI may have a meandering layout in plan view.

FIG. 3B is a perspective view of a Fin-FET SG-MONOS shown in FIG. 3A. FIG. 3B omits the interlayer insulating film and the interconnection over an element isolation film EI and each element, a cap insulating film over the control gate electrode CG, and a cap insulating film over the memory gate electrode MG for better understanding of the structure of the memory cell region. The memory cell MC is formed on the fin FI in the memory cell region. As shown in FIG. 3B, the control gate electrode CG and the memory gate electrode MG each intersect the fin FI while extending in the Y direction so as to straddle the fin FI.

FIG. 3C is a sectional view along a line A-A′ in FIG. 3A. Although a plurality of elements are actually arranged on one fin FI, FIG. 3C shows only one memory cell MC on the fin FI.

As shown in FIG. 3C, an oxidized layer CGO is formed in the upper surface of the control gate electrode CG. When the control gate electrode CG is made of aluminum (Al), the oxidized layer CGO is an aluminum oxide layer (AlO layer).

As shown in FIG. 3C, the upper surface and the side surfaces of the fin FI, in which the diffusion region D1 configuring the source-drain region of the memory cell region, are covered with the silicide layer S1. The silicide layer S1 is made of nickel silicide (NiSi), for example. The silicide layer S1 includes a layer extending along the upper surface and the side surface of the fin FI.

As shown in FIGS. 3B and 3C, the lower part of each side surface of the fin FI is surrounded by the element isolation film EI formed on the main surface of the semiconductor substrate SB. That is, the fins are isolated from each other by the element isolation film EI.

The control gate electrode CG is formed on the upper surface and the side surfaces of the fin FI via the gate insulating film GI, the High-k film HK, and the Vth control metal film VM, and the memory gate electrode MG is formed via the ONO film ON in a region adjacent to the control gate electrode CG in a long side direction (X direction) of the fin FI. The sidewall spacer SO is provided between the control gate electrode CG and the memory gate electrode MG, and the control gate electrode CG and the memory gate electrode MG are electrically isolated from each other by the sidewall spacer SO.

The gate insulating film GI is thermally-oxidized film (silicon oxide film) formed by thermally oxidizing the main surface and the side surfaces of the fin FI as the projecting semiconductor layer of the semiconductor substrate SB made of silicon, and has a thickness of 2 nm, for example. The ONO film ON includes the silicon oxide film OX1 including a thermally-oxidized film (silicon oxide film) formed by thermally oxidizing the main surface and the side surfaces of the fin FI as the projecting semiconductor layer of the semiconductor substrate SB made of silicon, the silicon nitride film NF formed on the silicon oxide film OX1, and the silicon oxide film OX2 formed on the silicon nitride film NF. The silicon nitride film NF serves as a charge storage part (charge storage layer) of the memory cell MC. For example, the silicon oxide film OX1 has a thickness of 4 nm, the silicon nitride film NF has a thickness of 7 nm, and the silicon oxide film OX2 has a thickness of 9 nm.

That is, the ONO film ON has a stacked structure including the silicon oxide film OX1, the silicon nitride film NF, and the silicon oxide film OX2 stacked in this order (in ascending order) from the upper surface side of the fin FI and from the side surface side of the control gate electrode CG. The ONO film ON has a thickness of, for example, 20 nm, which is larger than the thickness of the gate insulating film GI below the control gate electrode CG. The silicon oxide film OX2 may be replaced with a silicon oxynitride film.

The control gate electrode CG extends along the upper surface and the side surfaces of the fin FI and along the upper surface of the element isolation film EI in a short side direction (Y direction) of the fin FI while the gate insulating film GI, the High-k film HK, and the Vth control metal film VM are provided therebetween. Similarly, the memory gate electrode MG extends along the main surface and the side surfaces of the fin FI and the upper surface of the element isolation film EI in the short side direction of the fin FI while the ONO film ON is provided therebetween.

The side surfaces of a memory cell MC pattern including the control gate electrode CG and the memory gate electrode MG are covered with the silicon nitride film SN and the silicon nitride film CE. The silicon nitride film CE also serves as a contact etching stop liner film (CESL film) for forming the contact plugs (vias) CP in the interlayer insulating film IL.

As shown in FIG. 3C, a source-drain region pair is formed in the upper surface of the fin FI so as to sandwich the upper surface of the fin FI directly below that pattern including the control gate electrode CG. Each of the source and drain regions has the extension region EX as the n⁻-type semiconductor region and the diffusion region D1 as the n⁺-type semiconductor region. The diffusion region D1 has a higher impurity concentration and a deeper depth than the extension region EX. The extension region EX and the diffusion region D1 are in contact with each other in each of the source and drain regions, and the extension region EX is located in the upper surface of the fin FI more directly below the pattern, i.e., on a side closer to the channel region than the diffusion region Dl.

The drain region MD is adjacent to the fin FI directly below the control gate electrode CG, and the source region MS is adjacent to the fin FI directly below the memory gate electrode MG. Specifically, the source-drain regions sandwich the pattern including the control gate electrode CG and the memory gate electrode MG in plan view, and the drain region MD is located on a side close to the control gate electrode CG, while the source region MS is located on a side close to the memory gate electrode MG. In other words, the drain region MD is adjacent to the control gate electrode CG while the source region MS is adjacent to the memory gate electrode MG in plan view.

As described above, formation of the source-drain region, which has a structure including the extension region EX having a low impurity concentration and the diffusion region D1 having a high impurity concentration, i.e., a lightly doped drain (LDD) structure, makes it possible to improve short channel characteristics of the transistor having that source-drain region. That source region corresponds to the source region MS shown in FIG. 3A, and that drain region corresponds to the drain region MD shown in FIG. 3A.

As shown in FIG. 3C, the interlayer insulating film IL including, for example, a silicon oxide film is formed on the fin FI and the element isolation film EI. The interlayer insulating film IL covers the fin FI, the element isolation film EI, the control gate electrode CG, the memory gate electrode MG, the source-drain regions MS and MD, the insulating films IF4 and IF5, the silicon nitride film SN, the silicon nitride film CE, and the silicide layer S1. The upper surface of the interlayer insulating film IL is planarized.

A plurality of interconnections MW are formed on the interlayer insulating film IL, and are each electrically coupled to the source or drain region of the memory cell MC via the contact plug CP provided in the contact hole penetrating the interlayer insulating film IL. The bottom surface of the contact plug CP is directly in contact with the upper surface of the silicide layer S1, so that the contact plug CP is electrically coupled to the source-drain region via the silicide layer S1. The silicide layer S1 reduces a coupling resistance between the contact plug CP as a coupler including a metal film mainly containing, for example, tungsten (W) and the source-drain region in the fin FI including semiconductor.

In an undepicted power feeding region for the control gate electrode CG, the oxidized layer CGO on the control gate electrode CG is removed, and the contact plug CP is coupled to the upper surface of the control gate electrode CG. In an undepicted power feeding region for the memory gate electrode MG, the contact plug CP is coupled to the upper surface of the memory gate electrode MG.

The memory cell MC is the nonvolatile memory element including the control gate electrode CG, the memory gate electrode MG, the drain region MD, and the source region MS. The control gate electrode CG and the source-drain region configure the control transistor, the memory gate electrode MG and the source-drain region configure the memory transistor, and the memory cell MC is configured by the control transistor and the memory transistor. That is, the control transistor and the memory transistor share the source-drain region. A distance between the drain and source regions in the gate length direction (X direction) of the control gate electrode CG or the memory gate electrode MG corresponds to the channel length of the memory cell MC. The control transistor and the memory transistor are each a Fin FET having the surface of the fin FI as a channel.

### Method of Manufacturing Semiconductor Device of First Example

A method of manufacturing the memory cell structure of the semiconductor device (SG-MONOS) of the first example shown in FIG. 1 is now described with reference to FIGS. 4 to 19.

First, an undepicted element isolation region EI is formed on the semiconductor substrate SB, and then a well is formed by ion implantation. After the channel implantation, the gate insulating film of the MG-MOS is formed on the semiconductor substrate SB. The gate insulating film includes a stacked film of the silicon oxide film OX1 (formed to a thickness of about 2 to 5 nm by a thermal oxidation process, for example), the silicon nitride film NF (formed to a thickness of about 5 to 15 nm by a CVD process, for example) on the silicon oxide film OX1, and the silicon oxide film OX2 or the silicon oxynitride film (formed to a thickness of about 5 to 15 nm by a CVD process, for example) on the silicon nitride film NF.

The stacked film can be regarded as a so-called oxide-nitride-oxide (ONO) film. The stacked film may include, for example, an AHA film (stacked film of alumina (Al₂O₃), hafnium silicate (HfSiO), and Al₂O₃) instead of the OHO film.

Subsequently, as shown in FIG. 4, the polysilicon film PS (thickness of about 40 to 100 nm, for example) to be the memory gate electrode MG, and a silicon nitride film (SiN film, about 20 to 100 nm thick, for example) as a cap insulating film HM are formed in ascending order by a CVD process. Subsequently, the memory gate electrode MG is formed in the memory cell region by photolithography and anisotropic dry etching. The formed polysilicon film PS is subjected to p-type doping by ion implantation and annealing treatment.

Subsequently, as shown in FIG. 5, a sidewall-shaped silicon oxynitride film (SiON film) is formed (about 5 to 15 nm thick by a CVD process, for example) on each sidewall of the memory gate electrode MG and the cap insulating film HM. Subsequently, the sidewall (sidewall spacer) SO is formed by anisotropic dry etching.

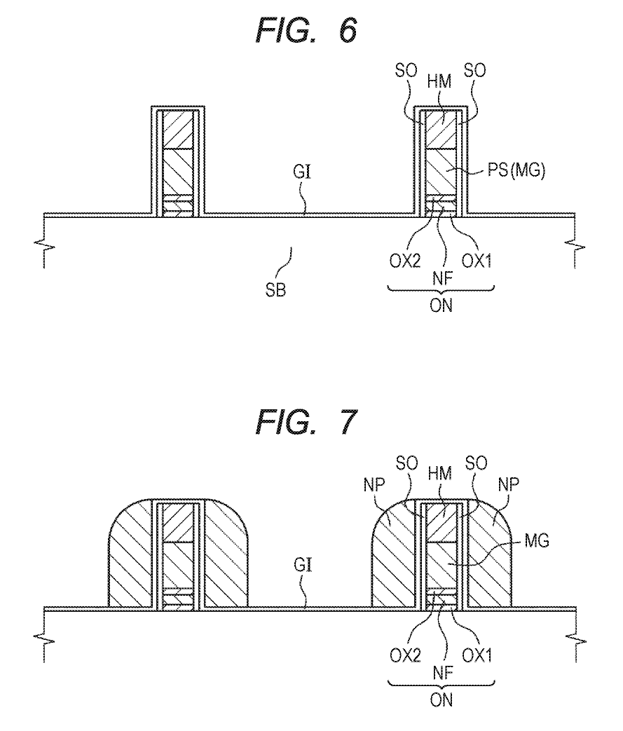

Subsequently, as shown in FIG. 6, a silicon oxide film to be the gate insulating film GI is formed on the entire surface of the semiconductor substrate SB to a thickness of about 2 to 4 nm by a thermal oxidation process, for example.

Subsequently, as shown in FIG. 7, an undoped polysilicon film NP is formed over the entire surface of the semiconductor substrate SB to a thickness of about 40 to 80 nm by a CVD process, for example. Subsequently, anisotropic etching is performed to form a sidewall-shaped control gate electrode CG (polysilicon film) over each sidewall of the memory gate electrode MG and the cap insulating film HM.

Subsequently, as shown in FIG. 8, one side (source side) of the sidewall-shaped polysilicon film is removed from the memory cell region by photolithography and isotropic dry etching.

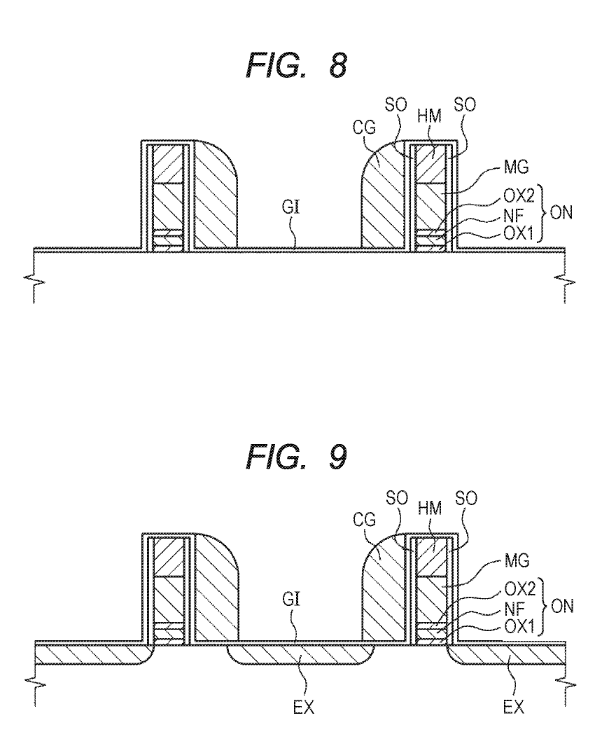

Subsequently, as shown in FIG. 9, an n-type LDD (extension region EX) is formed in the source/drain region of the memory cell MC by photolithography and ion implantation. The ion implantation may include Halo implantation or Pocket implantation (not shown), or may be performed under different conditions between the source and drain regions.

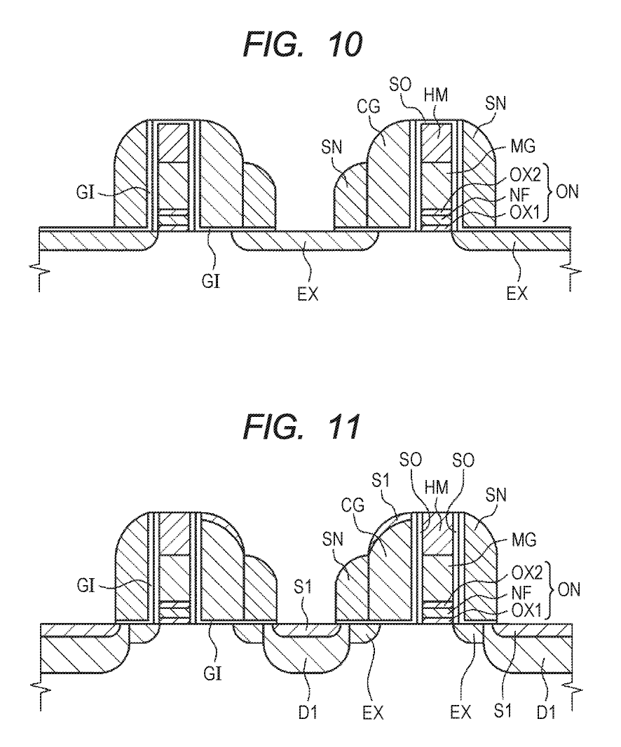

Subsequently, as shown in FIG. 10, a sidewall (silicon nitride film SN) of a silicon nitride film is formed on the sidewall of the memory gate electrode MG or a dummy CG electrode of the memory cell MC. Width of the sidewall (silicon nitride film SN) may be different or the same between the memory cell MC and a peripheral circuit. The width of the sidewall (silicon nitride film SN) of the memory cell MC is about 10 to 50 nm, for example.

Subsequently, as shown in FIG. 11, an n⁺-type source/drain (diffusion region D1) is formed in the source/drain region of each of the memory cell MC and the peripheral circuit by photolithography and ion implantation. Subsequently, the metal silicide layer S1 is formed on the semiconductor substrate SB. At this time, the metal silicide layer S1 is also formed on the surface of the polysilicon film of the control gate electrode CG.

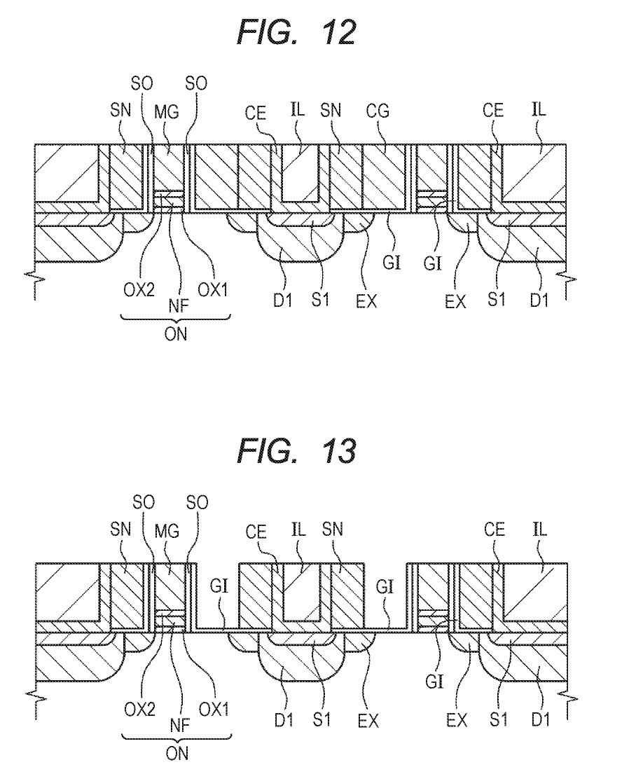

Subsequently, as shown in FIG. 12, the silicon nitride film CE having a thickness of, for example, about 10 to 40 nm is formed as the contact etching stop liner film (CESL film) over the semiconductor substrate SB, and then a P-TEOS oxide film or an O₃-TEOS oxide film having a thickness of, for example, about 400 to 600 nm is formed as the interlayer insulating film IL by a CVD process. Subsequently, CMP polishing is performed to expose the surface of the polysilicon film of each of the memory gate electrode MG of the memory cell MC and the dummy gate electrode of the peripheral circuit.

Subsequently, as shown in FIG. 13, the polysilicon film (undoped polysilicon film NP) of the control gate electrode

CG is removed by wet etching. Since the wet etching is performed based on a shavable property of the undoped polysilicon film NP of the control gate electrode CG and a less shavable property of the p-type polysilicon film of the memory gate electrode MG, wet etching using ammonia water (NH₄OH), APM (mixture of ammonia water (NH₄OH) and hydrogen peroxide solution (H₂O₂)), or the like is performed.

When the polysilicon film (undoped polysilicon film NP) of the control gate electrode CG is removed by the wet etching, the underlying thermally-oxidized film (gate insulating film GI) is not etched and remains due to high selectivity of the wet etching.

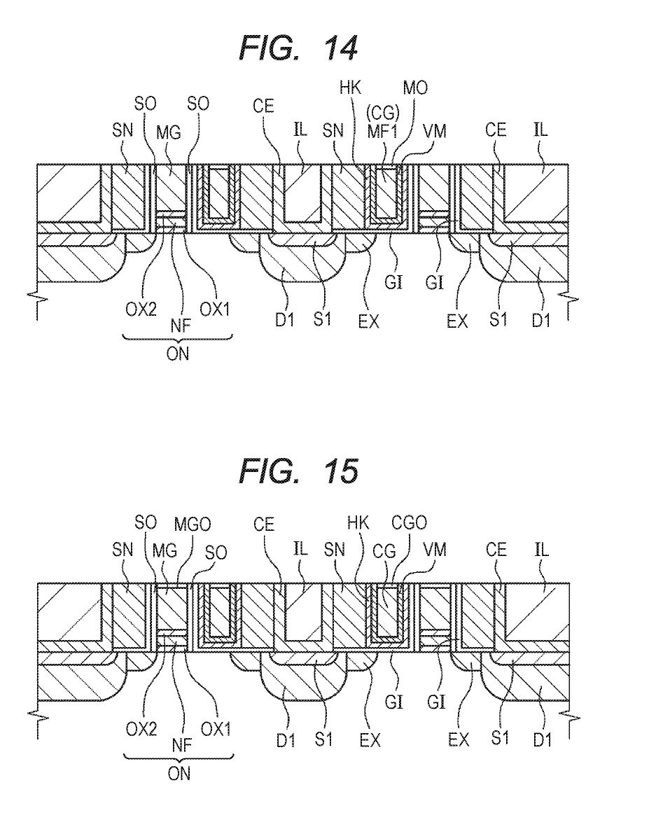

Subsequently, as shown in FIG. 14, the High-k film HK (including, for example, hafnium oxide (HfO₂), zirconium oxide (ZrO₂), aluminum oxide (Al₂O₃)) is formed to a thickness of about 1 to 3 nm over the semiconductor substrate SB by, for example, an ALD process so as to be buried in a trench formed by removing the polysilicon film (undoped polysilicon film NP) of the control gate electrode CG. A titanium nitride (TiN) film to be the Vth control metal film VM is formed to a thickness of about 2 to 3 nm by, for example, a PVD process directly over the High-k film HK. Subsequently, a metal layer (metal film MF1) of aluminum (Al) or the like is formed over the semiconductor substrate SB to fill the trench by, for example, a PVD process, and planarization is performed by CMP polishing so as to leave the metal layer in the memory cell MC, and thus the metal gate electrode is formed.

At this time, since the upper part of each of the memory gate electrode MG (polysilicon film PS) and the control gate electrode CG (aluminum film) is oxidized by the hydrogen peroxide solution (H₂O₂) used in the CMP polishing step, a thin silicon oxide (SiO₂) layer (not shown) is formed in the upper part of the memory gate electrode MG (polysilicon film PS), and a thin aluminum oxide (Al₂O₃) layer MO is formed in the upper part of the control gate electrode CG (aluminum film).

The thin aluminum oxide (Al₂O₃) layer MO has a thickness of about 5 nm depending on a condition of the CMP polishing step.

Subsequently, as shown in FIG. 15, the surface of the semiconductor substrate SB is oxidized by low-temperature oxidation or plasma oxidation, for example. At this time, a silicon oxide (SiO₂) film MGO is formed in the surface (upper part) of the memory gate electrode MG, and an aluminum oxide (Al₂O₃) film CGO is formed in the surface (upper part) of the control gate electrode CG. The aluminum oxide (Al₂O₃) film CGO has a thickness of about 5 to 20 nm. A preferred thickness of the control gate electrode CG is roughly as follows: High-k film HK and Vth control metal film VM: metal layer (Al): aluminum oxide (Al₂O₃) film CGO=5 to 15 nm: 40 to 50 nm:5 to 20 nm in ascending order.

Such surface oxidation treatment (low-temperature oxidation or plasma oxidation) must be performed at a temperature equal to or lower than the melting point (about 660° C.) of aluminum as a material of the control gate electrode CG, and is preferably performed at a temperature of about 400° C. or lower in light of durability and reliability of aluminum as the gate electrode.

A yield rate of the semiconductor device is expectably improved by the surface oxidation treatment (low-temperature oxidation or plasma oxidation). For example, a metal residue (for example, CMP residue), causing a defect (for example, short-circuit) that may occur in the surface of the semiconductor substrate SB during formation of the metal gate electrode, is oxidized to lose conductivity, making it possible to prevent occurrence of defects.

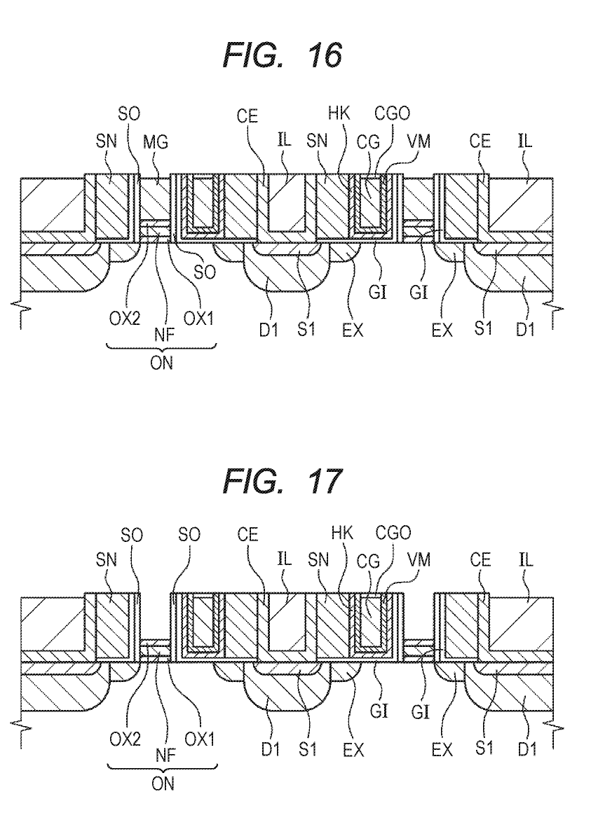

Subsequently, as shown in FIG. 16, the silicon oxide (SiO₂) film MGO on the memory gate electrode MG is removed by etching to expose the p-type polysilicon film PS of the memory gate electrode MG. Wet etching (using diluted HF, for example) or isotropic dry etching (using CF₄ gas or SF₆ gas, for example) is performed as the etching to remove the silicon oxide film MGO on the memory gate electrode MG. At this time, the surface of the control gate electrode CG is protected by the aluminum oxide (Al₂O₃) film CGO. The interlayer insulating film IL including the P-TEOS oxide film or the O₃-TEOS oxide interlayer film is recessed by the etching, so that a difference in level is formed with respect to the silicon nitride film CE as the CESL film.

Subsequently, as shown in FIG. 17, the p-type polysilicon film PS of the memory gate electrode MG is removed by etching. Since the etching is performed to etch the p-type polysilicon film PS, isotropic dry etching (using Cl₂ gas or HBr gas, for example) is performed instead of wet etching. At this time, the surface of the control gate electrode CG is protected by the aluminum oxide (Al₂O₃) film CGO.

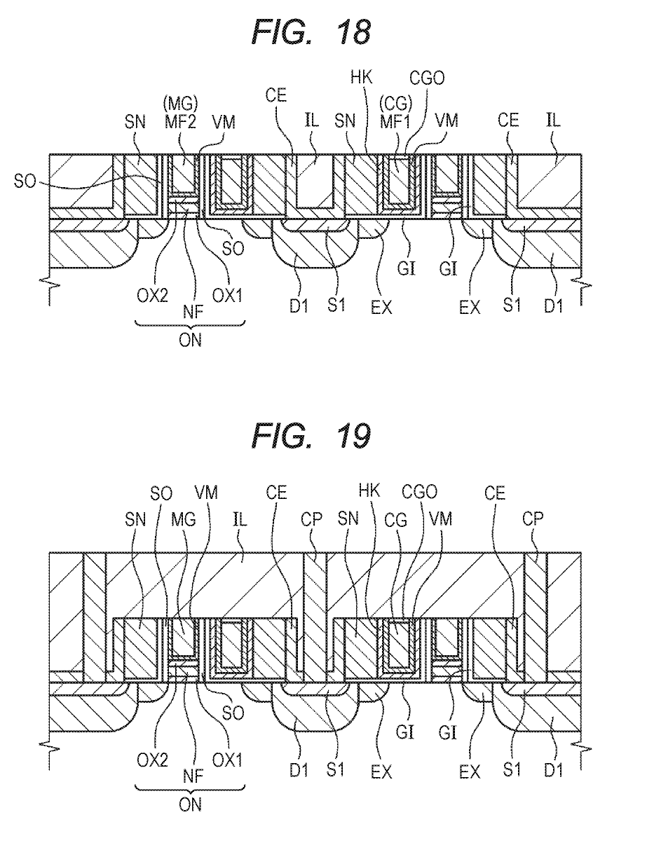

Subsequently, as shown in FIG. 18, a titanium nitride (TiN) film to be the Vth control metal film VM is formed to a thickness of about 2 to 3 nm by, for example, a PVD process directly over the ONO film ON (or AHA film) so as to cover the inside of a trench formed by removing the p-type polysilicon film PS of the memory gate electrode MG. Subsequently, a metal layer (metal film MF2) of aluminum (Al) or the like is formed over the semiconductor substrate SB to fill the trench by, for example, a PVD process, and planarization is performed by CMP polishing so as to leave the metal layer in the memory cell MC, and thus the metal gate electrode is formed. At this time, the difference in level between the interlayer insulating film IL and the silicon nitride film CE (CESL film) as described above (formed in the step described with FIG. 16) is eliminated by the CMP polishing.

Subsequently, as shown in FIG. 19, an interlayer insulating film IL including a P-TEOS oxide film or an O₃-TEOS oxide film is formed over the semiconductor substrate SB by a CVD process, for example. Subsequently, contact holes are formed by photolithography and dry etching. A conductive contact plug (via) CP made of tungsten (W) or the like is formed as a coupling conductor part in each contact hole by a CVD process and CMP polishing, for example. Subsequently, the interconnection MW (W interconnection, Al interconnection, or Cu interconnection) as shown in FIGS. 3A to 3C is formed by photolithography and dry etching or by an interconnect damascene technique.

The memory cell structure of the semiconductor device (SG-MONOS) of the first example as shown in FIG. 1 is completed through the above-described manufacturing method.

According to the memory cell structure of the semiconductor device (SG-MONOS) of the first example, the metal gate electrode is used for the control gate electrode CG as in the comparative example shown in FIG. 2, and the metal gate electrode is also used for the metal gate electrode MG. This makes it possible to suppress a variation in characteristics or an increase in resistance of the memory gate electrode MG (MG-MOS) associated with scaling (reduction in cell size) even if the memory cell structure is scaled.

According to the above-described manufacturing method, the aluminum oxide (Al₂O₃) film CGO to be a protective film is formed in the surface of the control gate electrode CG by low-temperature oxidation or plasma oxidation, thereby the polysilicon film PS of the dummy metal gate electrode MG can be removed without affecting the control gate electrode CG, allowing metal substitution of the memory gate electrode MG without increasing the number of masks (number of steps) more than necessary.

Use of the polysilicon film (undoped polysilicon film NP) as the dummy material of the control gate electrode CG allows simultaneous removal of the polysilicon film in a logic circuit or the like other than the memory cell MC, and thus metal substitution can be performed without increasing the number of masks (number of steps) compared with the existing techniques.

Metal substitution of the control gate electrode CG can be performed separately from metal substitution of the memory gate electrode MG, allowing some degree of freedom on setting of Vth for each of the control gate electrode CG and the memory gate electrode MG.

The above-described memory cell structure and the manufacturing method thereof can also be applied to the fin field effect transistor (Fin-FET) as shown in FIGS. 3A to 3C.

### SECOND EXAMPLE

### Method of Manufacturing Semiconductor Device of Second Example

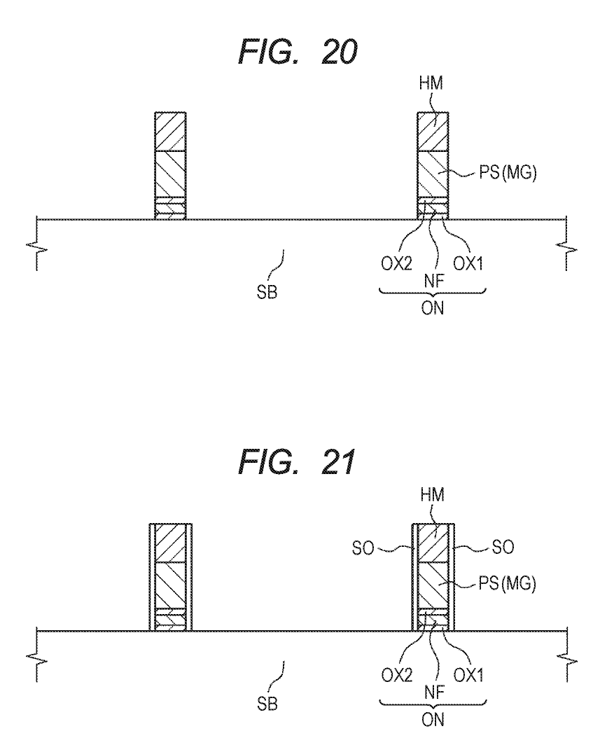

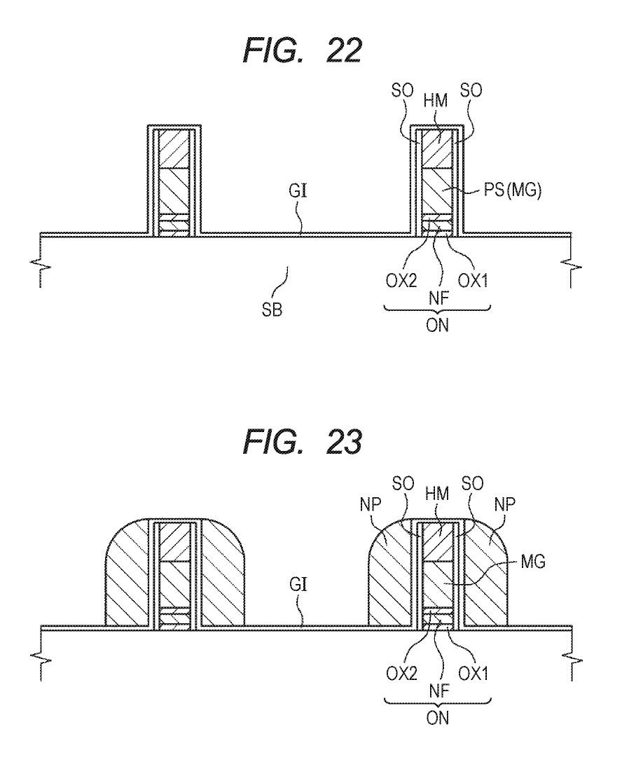

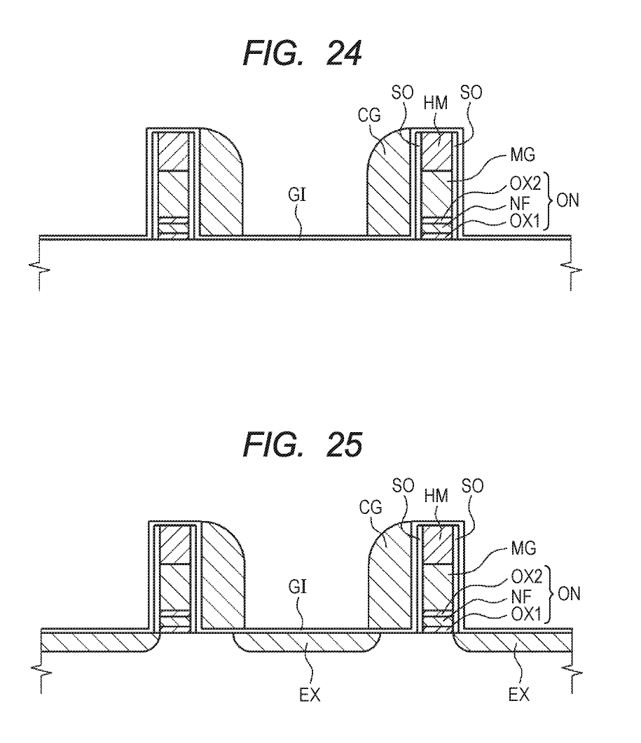

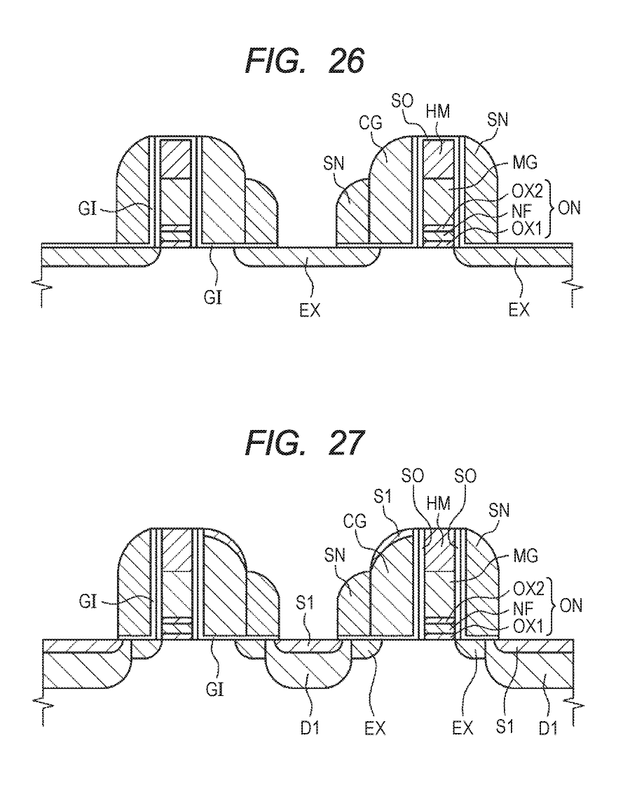

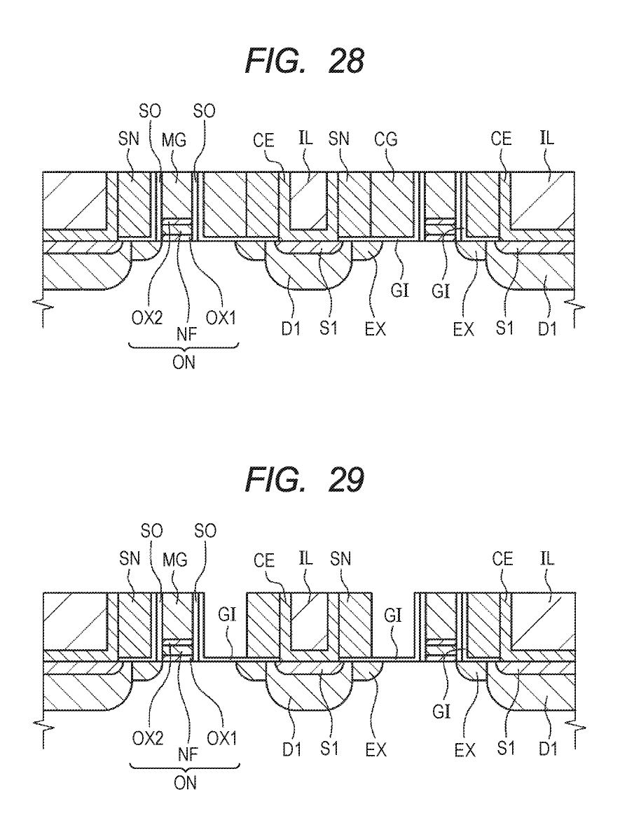

A method of manufacturing a semiconductor device of a second example is now described with reference to FIGS. 20 to 35. In the first example, the aluminum oxide (Al₂O₃) film CGO to be the protective film is formed in the surface of the control gate electrode CG by low-temperature oxidation or plasma oxidation. The second example is a modification of the first example, in which the protective layer is formed in the surface (upper part) of the control gate electrode CG by a different process.

FIGS. 20 to 35 are sectional views of steps of a method for manufacturing the semiconductor device (SG-MONOS) shown in FIG. 1.

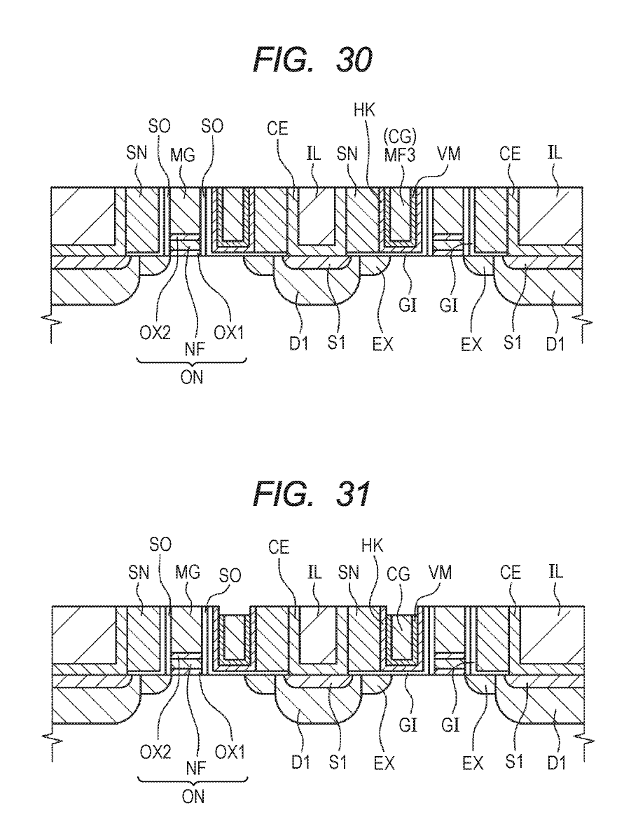

Since FIGS. 20 to 29 are the same as FIGS. 4 to 13 of the first example, duplicated description is omitted. FIG. 30 and subsequent figures are described below.

As shown in FIG. 30, the High-k film HK (including, for example, hafnium oxide (HfO₂), zirconium oxide (ZrO₂), aluminum oxide (Al₂O₃)) is formed to a thickness of about 1 to 3 nm on the semiconductor substrate SB by, for example, an ALD process so as to cover the inside of a trench formed by removing the polysilicon film (undoped polysilicon film NP) of the control gate electrode CG. A titanium nitride (TiN) film to be the Vth control metal film VM is formed to a thickness of about 2 to 3 nm by, for example, a PVD process directly over the High-k film HK. Subsequently, a metal layer (metal film MF3) of tungsten (W) or the like is formed over the semiconductor substrate SB to fill the trench by, for example, a PVD process, and planarization is performed by CMP polishing so as to leave the metal layer in the memory cell MC, and thus the metal gate electrode is formed.

Subsequently, as shown in FIG. 31, the buried tungsten (W) of the control gate electrode CG is partially etched by wet etching using, for example, APM (mixture of ammonia water (NH₄OH) and hydrogen peroxide solution (H₂O₂)) to form a recess of about 5 to 20 nm in the upper part of the control gate electrode CG.

A yield rate of the semiconductor device is expectably improved by the wet etching. For example, a metal residue (for example, CMP residue), causing a defect (for example, short-circuit) that may occur in the surface of the semiconductor substrate SB during formation of the metal gate electrode, is oxidized to lose conductivity, making it possible to prevent occurrence of defects.

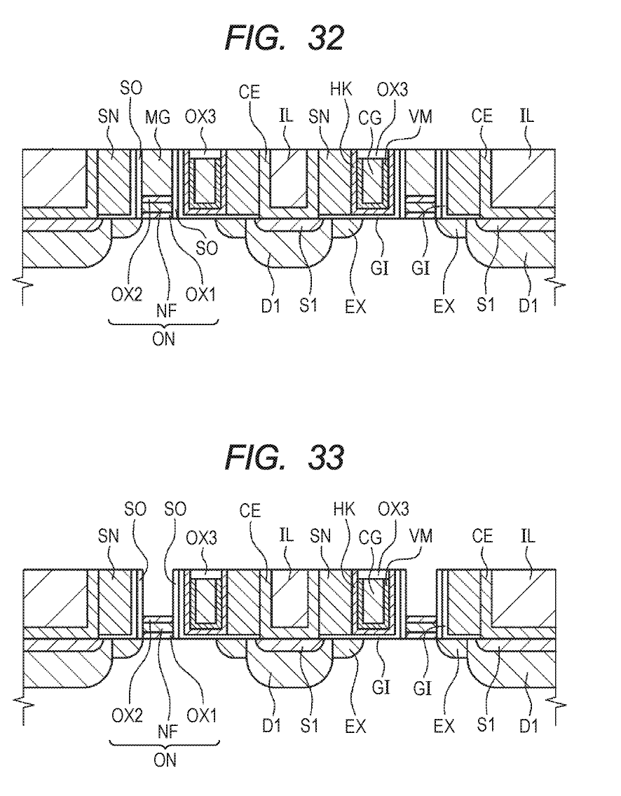

Subsequently, as shown in FIG. 32, a silicon oxide film (for example, a P-TEOS oxide film or an O₃-TEOS oxide film) is formed over the semiconductor substrate SB by a CVD process, and then the recess in the upper part of the control gate electrode CG is filled with a silicon oxide film OX3 by CMP polishing, so that the upper part of the control gate electrode CG is covered with the silicon oxide film OX3. At this time, a recess, which corresponds to a mark of the metal residue (for example, CMP residue) removed by the wet etching, is also filled with the silicon oxide film OX3 and thus planarization is achieved.

Subsequently, as shown in FIG. 33, the p-type polysilicon film PS of the memory gate electrode MG is removed by etching. Since the etching is performed to etch the p-type polysilicon PS, isotropic dry etching (using Cl₂ gas or HBr gas, for example) is performed instead of wet etching. At this time, the surface of the control gate electrode CG is protected by the silicon oxide film OX3 (for example, a P-TEOS oxide film or an O₃-TEOS oxide film).

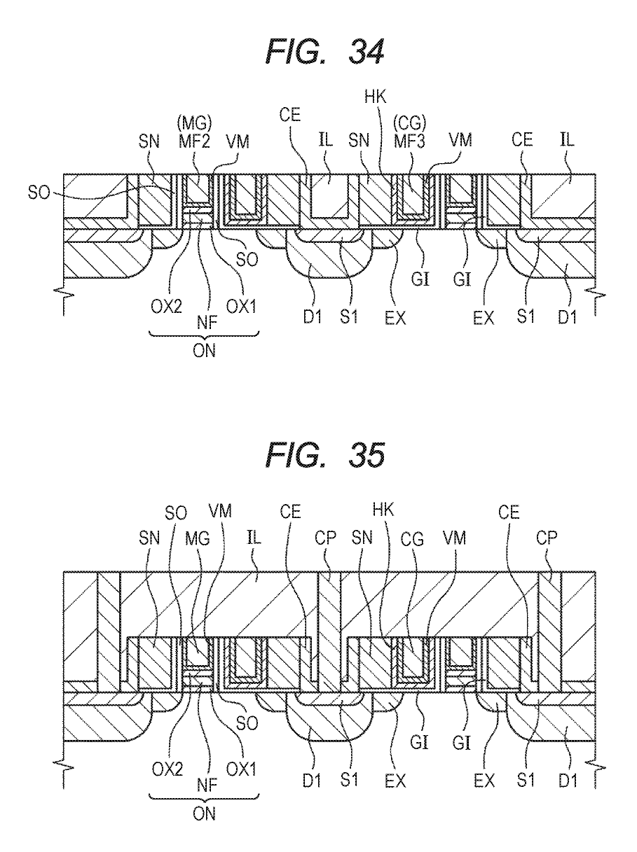

Subsequently, as shown in FIG. 34, a titanium nitride (TiN) film to be the Vth control metal film VM is formed to a thickness of about 2 to 3 nm by, for example, a PVD process directly over the ONO film ON (or AHA film) so as to cover the inside of a trench formed by removing the p-type polysilicon film PS of the memory gate electrode MG. Subsequently, over the semiconductor substrate SB, filling the trench with a metal layer (metal film MF2) of aluminum (Al) or the like by, for example, a PVD process, and planarization is performed by CMP polishing so as to leave the metal layer in the memory cell MC, and thus the metal gate electrode is formed.

Subsequently, as shown in FIG. 35, an interlayer insulating film IL including a P-TEOS oxide film or an O₃-TEOS oxide film is formed over the semiconductor substrate SB by a CVD process, for example. Subsequently, contact holes are formed by photolithography and dry etching. A conductive contact plug (via) CP made of tungsten (W) or the like is formed as a coupling conductor part in each contact hole by a CVD process and CMP polishing, for example. Subsequently, an interconnection MW (W interconnection, Al interconnection, or Cu interconnection) as shown in FIGS. 3A to 3C is formed by photolithography and dry etching or by an interconnect damascene technique.

The memory cell structure of the semiconductor device (SG-MONOS) of the second example as shown in FIG. 1 is completed through the above-described manufacturing method.

### THIRD EXAMPLE

### Method of Manufacturing Semiconductor Device of Third Example

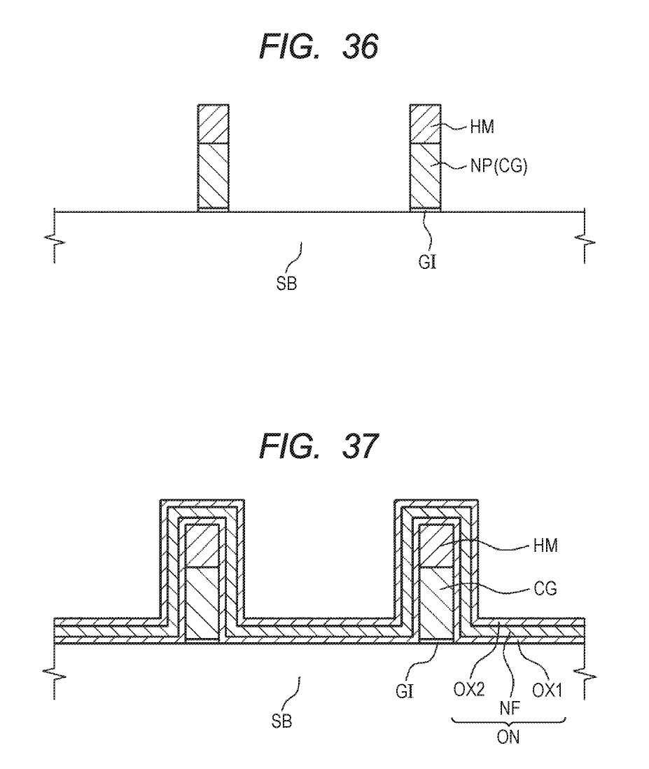

A method of manufacturing a semiconductor device of a third example is now described with reference to FIGS. 36 to 51. Although the MG-first manufacturing method of the split gate MONOS (SG-MONOS), in which the memory gate electrode MG is first formed on the semiconductor substrate SB, has been described in the first example, a CG-first manufacturing method, in which the control gate electrode CG is first formed, is described in the third example.

The third example is the same as the first example in that the aluminum oxide (Al₂O₃) film CGO to be the protective film is formed in the surface of the control gate electrode CG by low-temperature oxidation or plasma oxidation.

First, an undepicted element isolation region EI is formed on the semiconductor substrate SB, and then a well is formed by ion implantation. After the channel implantation, as shown in FIG. 36, a silicon oxide film (gate insulating film GI) is formed to a thickness of about 2 to 4 nm by a thermal oxidation process, for example. Subsequently, an undoped polysilicon film NP (about 40 to 100 nm thick, for example) to be the control gate electrode CG and a silicon nitride film (SiN film, about 20 to 100 nm thick, for example) are formed in ascending order by a CVD process. Subsequently, the control gate electrode CG is formed in the memory cell region by photolithography and anisotropic dry etching.

Subsequently, as shown in FIG. 37, the ONO film ON to be the gate insulating film of the memory gate electrode MG is formed on the sidewalls of the control gate electrode CG and on the semiconductor substrate SB. The gate insulating film (ONO film ON) includes a stacked film of the silicon oxide film OX1 (formed to a thickness of about 2 to 5 nm by a thermal oxidation process, for example), the silicon nitride film NF (formed to a thickness of about 5 to 15 nm by, for example, a CVD process) on the silicon oxide film OX1, and the silicon oxide film OX2 or a silicon oxynitride film (formed to a thickness of about 5 to 15 nm by, for example, a CVD process) on the silicon nitride film NF.

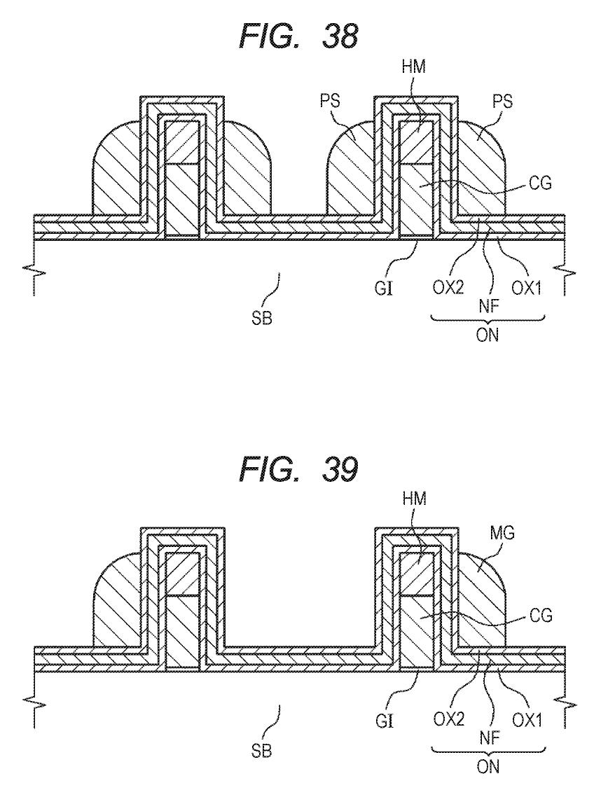

The stacked film can be regarded as a so-called oxide-nitride-oxide (ONO) film. The stacked film may include, for example, an AHA film (stacked film of alumina (Al₂O₃), hafnium silicate (HfSiO), and Al₂O₃ (AHA)) instead of the OHO film. Subsequently, as shown in FIG. 38, the polysilicon film PS is formed over the entire surface of the semiconductor substrate SB to a thickness of about 40 to 80 nm by a CVD process, for example. The polysilicon film PS is an undoped film. Subsequently, the polysilicon film PS is subjected to p-type doping by ion implantation and annealing treatment, and then subjected to anisotropic dry etching, thereby a sidewall-shaped memory gate electrode MG (polysilicon film PS) is formed over the sidewalls of the control gate electrode CG.

Subsequently, as shown in FIG. 39, one side (drain side) of the sidewall-shaped memory gate electrode MG (polysilicon film PS) is removed from the memory cell region by photolithography and isotropic dry etching.

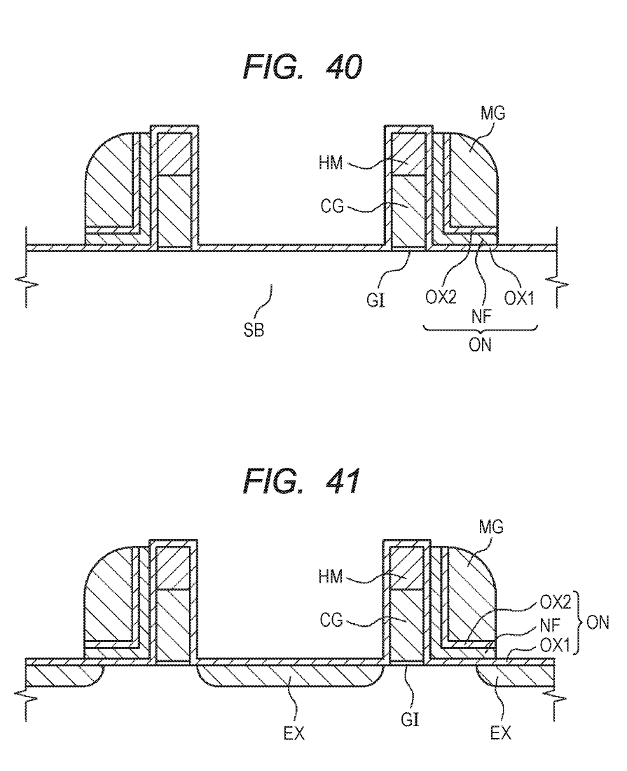

Subsequently, as shown in FIG. 40, the upper two films (the silicon oxide film OX2 and the silicon nitride film NF) of the ONO film ON exposed on the surface are removed by dry etching to leave the lowermost film (silicon oxide film OX1).

Subsequently, as shown in FIG. 41, an n-type LDD (extension region EX) is formed in the source/drain region of the memory cell MC by photolithography and ion implantation. The ion implantation may include Halo implantation or Pocket implantation (not shown), or may be performed under different conditions between the source and drain regions.

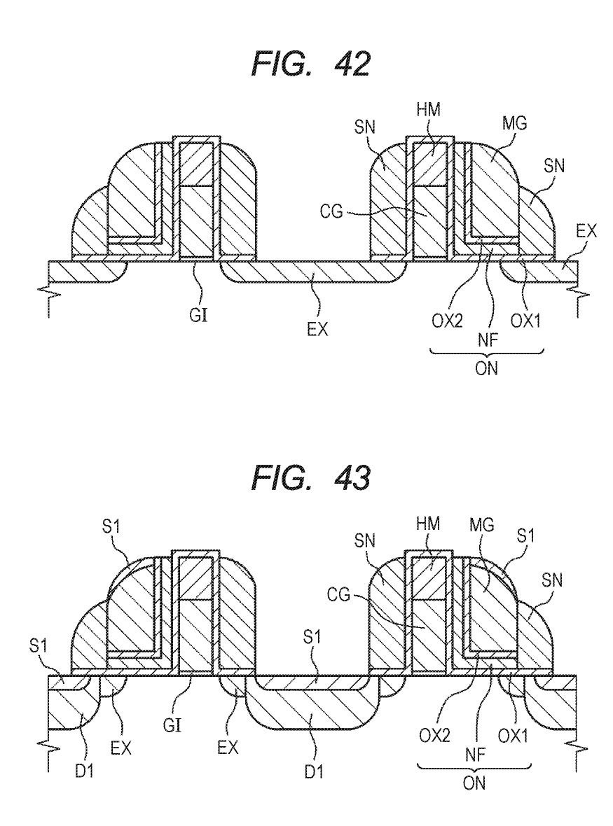

Subsequently, as shown in FIG. 42, a sidewall (silicon nitride film SN) of a silicon nitride film is formed on a sidewall of the memory gate electrode MG or a dummy CG electrode of the memory cell MC. Width of the sidewall (silicon nitride film SN) may be different or the same between the memory cell MC and a peripheral circuit. The width of the sidewall (silicon nitride film SN) of the memory cell MC is about 10 to 50 nm, for example.

Subsequently, as shown in FIG. 43, an n⁺-type source/drain (diffusion region D1) is formed in the source/drain region of each of the memory cell MC and the peripheral circuit by photolithography and ion implantation. Subsequently, the silicide layer S1 is formed on the semiconductor substrate SB. At this time, the metal silicide layer S1 is also formed on the surface of the polysilicon film of the metal gate electrode MG.

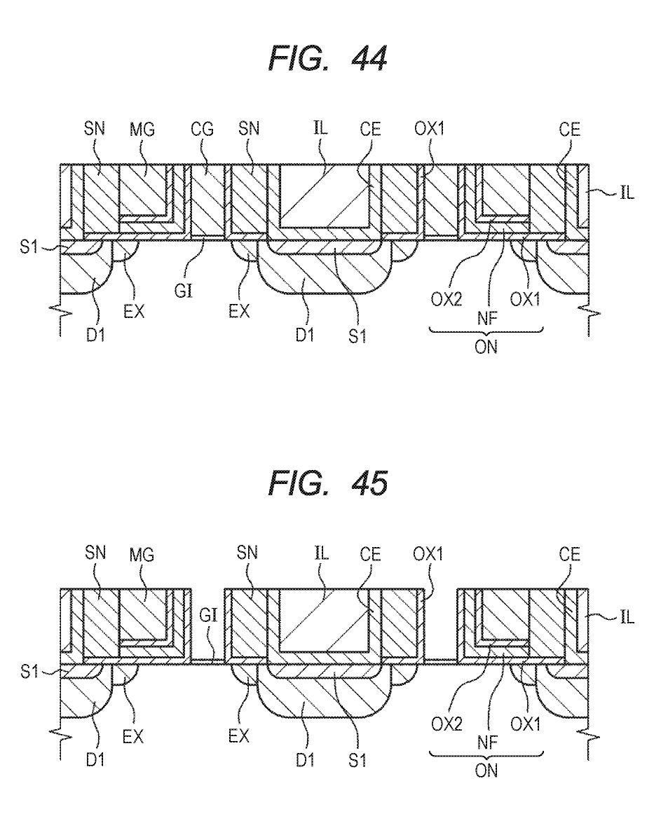

Subsequently, as shown in FIG. 44, the silicon nitride film CE having a thickness of, for example, about 10 to 40 nm is formed as the contact etching stop liner film (CESL film) over the semiconductor substrate SB, and then a P-TEOS oxide film or an O₃-TEOS oxide film having a thickness of, for example, about 400 to 600 nm is formed as the interlayer insulating film IL by a CVD process. Subsequently, CMP polishing is performed to expose the surface of the polysilicon film of each of the memory gate electrode MG of the memory cell MC and the dummy gate electrode of the peripheral circuit.

Subsequently, as shown in FIG. 45, the polysilicon film (undoped polysilicon film) of the control gate electrode CG is removed by wet etching. Since the wet etching is performed based on a shavable property of the undoped polysilicon film of the control gate electrode CG and a less shavable property of the p-type polysilicon film of the memory gate electrode MG, wet etching using ammonia water (NH₄OH), APM (mixture of ammonia water (NH₄OH) and hydrogen peroxide solution (H₂O₂)), or the like is performed.

When the polysilicon film (undoped polysilicon film NP) of the control gate electrode CG is removed by the wet etching, the underlying thermally-oxidized film (gate insulating film GI) is not etched and remains due to high selectivity of the wet etching.

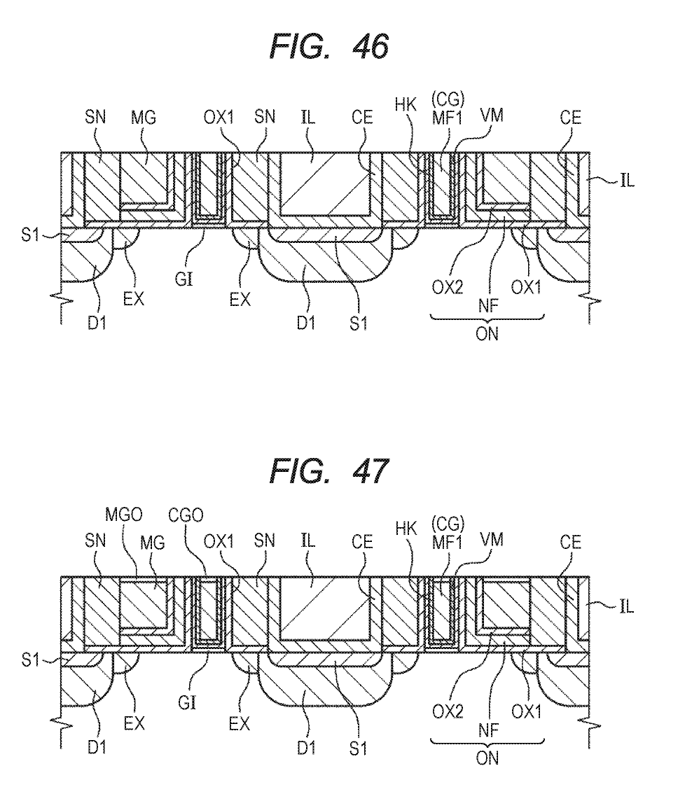

Subsequently, as shown in FIG. 46, the High-k film HK (including, for example, hafnium oxide (HfO₂), zirconium oxide (ZrO₂), aluminum oxide (Al₂O₃)) is formed to a thickness of about 1 to 3 nm over the semiconductor substrate SB by, for example, an ALD process so as to cover the inside of a trench formed by removing the polysilicon film (undoped polysilicon film) of the control gate electrode CG. A titanium nitride (TiN) film to be the Vth control metal film VM is formed to a thickness of about 2 to 3 nm by, for example, a PVD process directly over the High-k film HK. Subsequently, a metal layer (metal film MF1) of aluminum (Al) or the like is formed over the semiconductor substrate SB to fill the trench by, for example, a PVD process, and planarization is performed by CMP polishing so as to leave the metal layer in the memory cell MC, and thus the metal gate electrode is formed.

At this time, since the upper part of each of the memory gate electrode MG (polysilicon film PS) and the control gate electrode CG (aluminum film) is oxidized by the hydrogen peroxide solution (H₂O₂) used in the CMP polishing step, a thin silicon oxide (SiO₂) layer (not shown) is formed in the upper part of the memory gate electrode MG (polysilicon film PS), and a thin aluminum oxide (Al₂O₃) layer (not shown) is formed in the upper part of the control gate electrode CG (aluminum film). The thin aluminum oxide (Al₂O₃) layer has a thickness of about 5 nm depending on a condition of the CMP polishing step.

Subsequently, as shown in FIG. 47, the surface of the semiconductor substrate SB is oxidized by low-temperature oxidation or plasma oxidation, for example. At this time, a silicon oxide (SiO₂) film MGO is formed in the surface (upper part) of the memory gate electrode MG, and an aluminum oxide (Al₂O₃) film CGO is formed in the surface (upper part) of the control gate electrode CG. The aluminum oxide (Al₂O₃) film CGO has a thickness of about 5 to 20 nm. A preferred thickness of the control gate electrode CG is roughly as follows: High-k film HK and Vth control metal film VM: metal layer (Al): aluminum oxide (Al₂O₃) film CGO=5 to 15 nm: 40 to 50 nm: 5 to 20 nm in ascending order.

A yield rate of the semiconductor device is expectably improved by the surface oxidation treatment (low-temperature oxidation or plasma oxidation). For example, a metal residue (for example, CMP residue), causing a defect (for example, short-circuit) that may occur in the surface of the semiconductor substrate SB during formation of the metal gate electrode, is oxidized to lose conductivity, making it possible to prevent occurrence of defects.

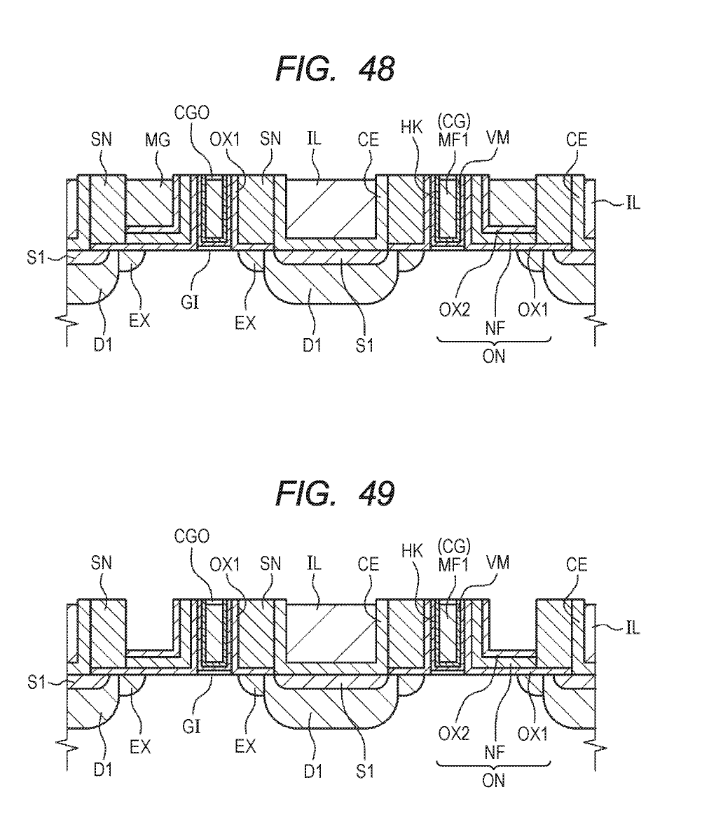

Subsequently, as shown in FIG. 48, the silicon oxide (SiO₂) film MGO on the memory gate electrode MG is removed by etching to expose the p-type polysilicon film of the memory gate electrode MG. Wet etching (using diluted HF, for example) or isotropic dry etching (using CF₄ gas or SF₆ gas, for example) is performed as the etching to remove the silicon oxide film MGO on the memory gate electrode MG. At this time, the surface of the control gate electrode CG is protected by the aluminum oxide (Al₂O₃) film CGO. The interlayer insulating film IL including the P-TEOS oxide film or the O₃-TEOS oxide interlayer film is recessed by the etching, so that a difference in level is formed with respect to the silicon nitride film CE as the CESL film.

Subsequently, as shown in FIG. 49, the p-type polysilicon film of the memory gate electrode MG is removed by etching. Since the etching is performed to etch the p-type polysilicon film PS, isotropic dry etching (using Cl₂ gas or HBr gas, for example) is performed instead of wet etching. At this time, the surface of the control gate electrode CG is protected by the aluminum oxide (Al₂O₃) film CGO.

Subsequently, as shown in FIG. 50, a titanium nitride (TiN) film to be the Vth control metal film VM is formed to a thickness of about 2 to 3 nm by, for example, a PVD process directly over the ONO film ON (or AHA film) so as to cover the inside of a trench formed by removing the p-type polysilicon film PS of the memory gate electrode MG. Subsequently, a metal layer (metal film MF2) of aluminum (Al) or the like is formed over the semiconductor substrate SB to fill the trench by, for example, a PVD process, and planarization is performed by CMP polishing so as to leave the metal layer in the memory cell MC, and thus the metal gate electrode is formed. At this time, the difference in level between the interlayer insulating film IL and the silicon nitride film CE (CESL film) as described above (formed in the step described with FIG. 48) is eliminated by the CMP polishing.

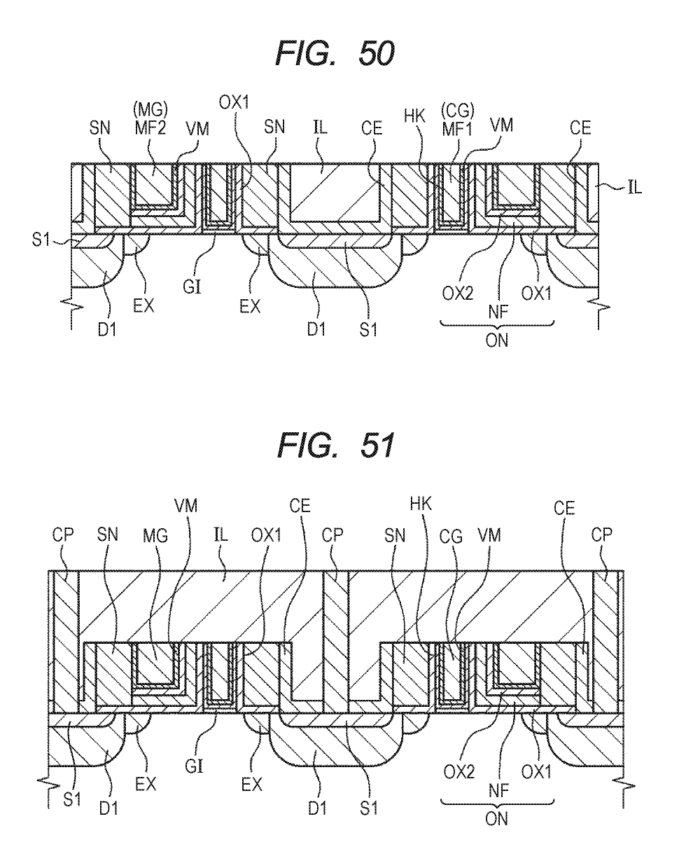

Subsequently, as shown in FIG. 51, an interlayer insulating film IL including a P-TEOS oxide film or an O₃-TEOS oxide film is formed over the semiconductor substrate SB by a CVD process, for example. Subsequently, contact holes are formed by photolithography and dry etching. A conductive contact plug (via) CP made of tungsten (W) or the like is formed as a coupling conductor part in each contact hole by a CVD process and CMP polishing, for example. Subsequently, an interconnection MW (W interconnection, Al interconnection, or Cu interconnection) as shown in FIGS. 3A to 3C is formed by photolithography and dry etching or by an interconnect damascene technique.

The memory cell structure of the semiconductor device (SG-MONOS) of the third example is completed through the above-described manufacturing method.

### FOURTH EXAMPLE

### Method of Manufacturing Semiconductor Device of Fourth Example

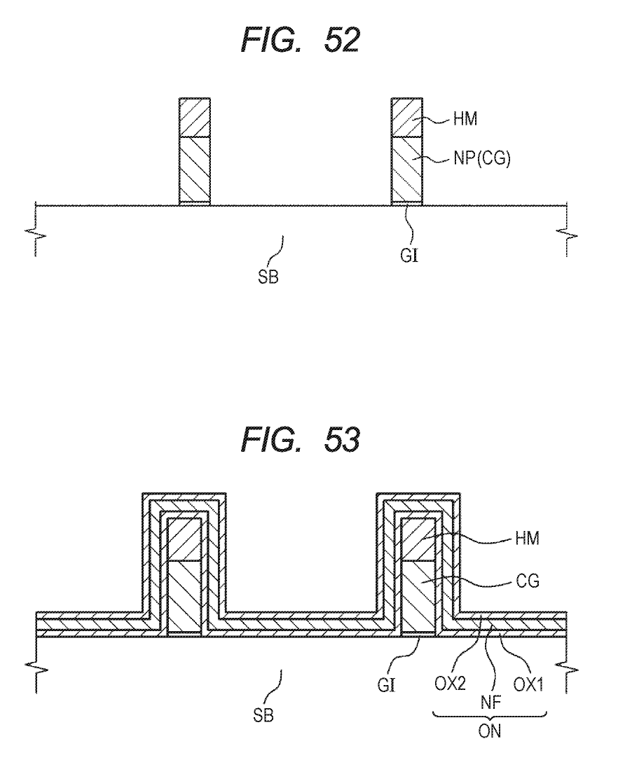

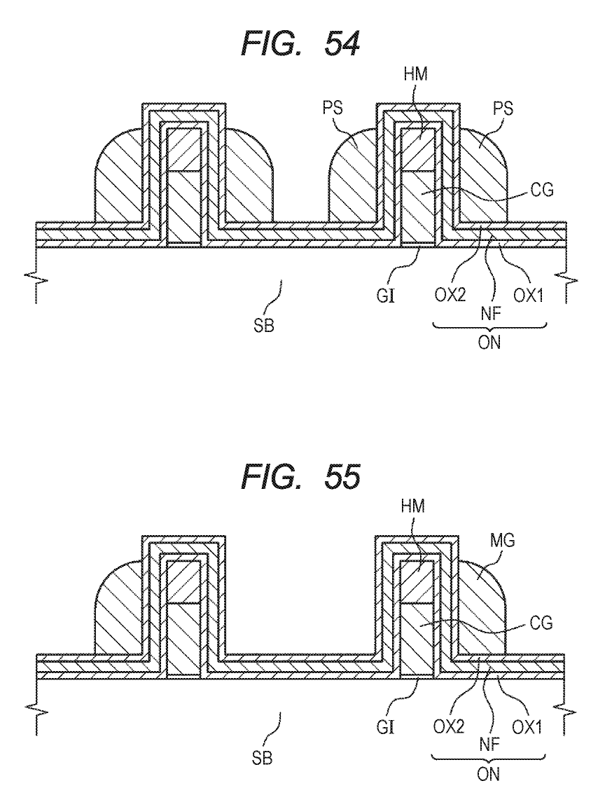

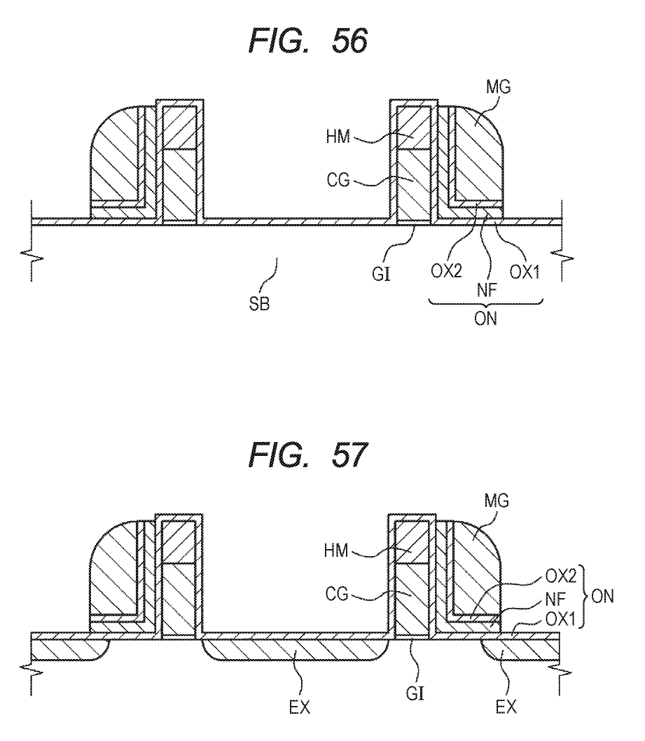

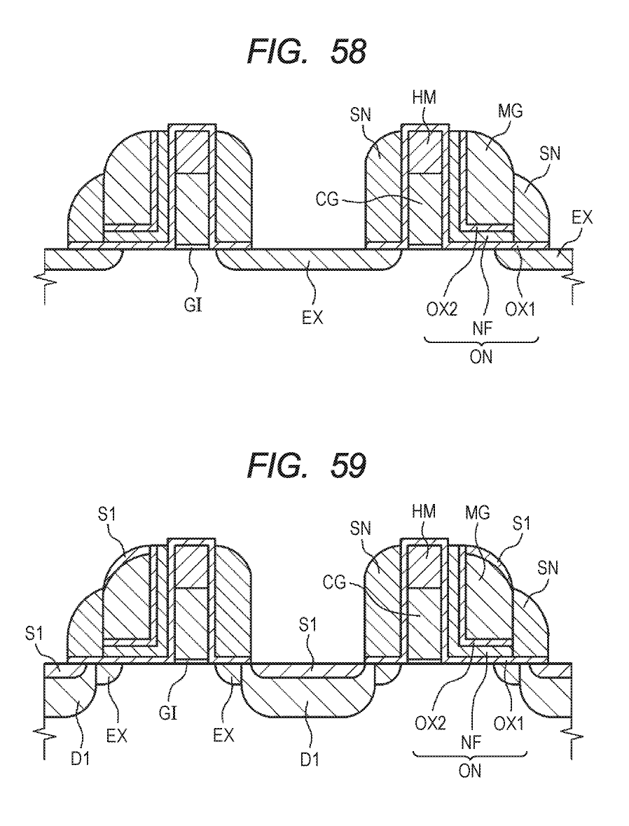

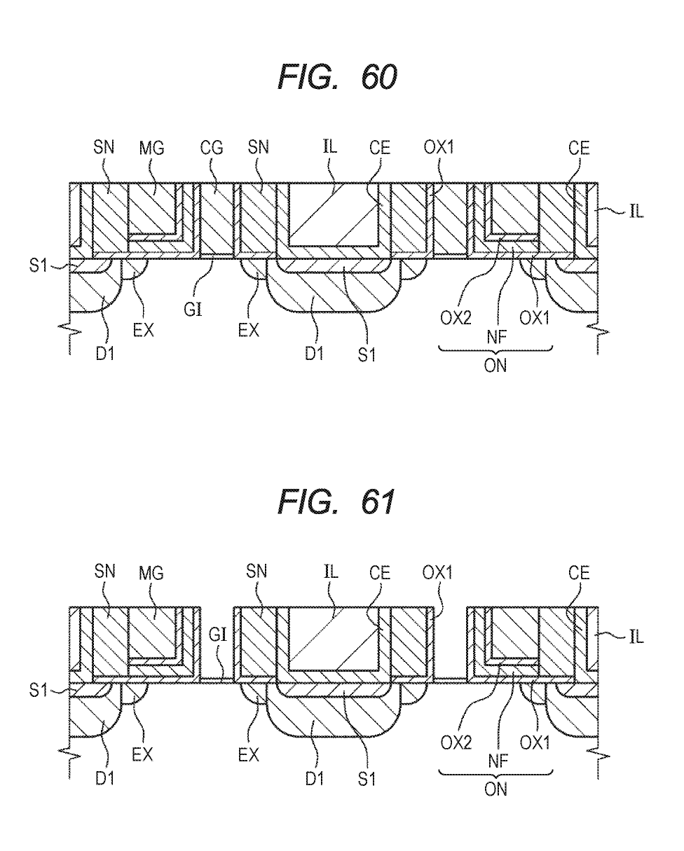

A method of manufacturing a semiconductor device of a fourth example is now described with reference to FIGS. 52 to 67. In the third example, the aluminum oxide (Al₂O₃) film CGO to be the protective film is formed in the surface of the control gate electrode CG by low-temperature oxidation or plasma oxidation. In the fourth example, as in the second example, a recess is formed in the upper part of the control gate electrode CG by wet etching, and the recess is filled with a silicon oxide film OX3 to form a protective film over the control gate electrode CG.

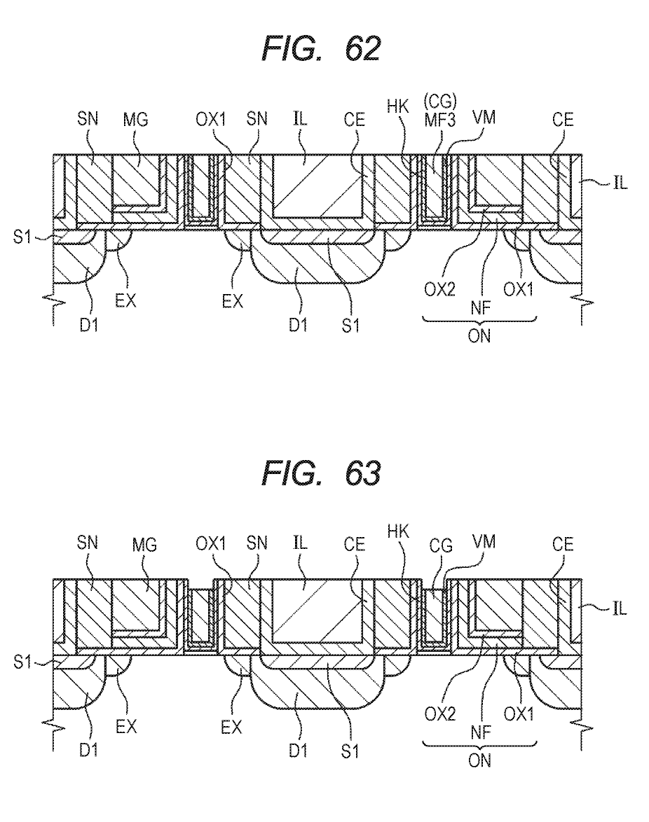

Since FIGS. 52 to 61 are the same as FIGS. 36 to 45 of the third example, duplicated description is omitted. FIG. 62 and subsequent figures are described below.

As shown in FIG. 62, the High-k film HK (including, for example, hafnium oxide (HfO₂), zirconium oxide (ZrO₂), aluminum oxide (Al₂O₃)) is formed to a thickness of about 1 to 3 nm on the semiconductor substrate SB by, for example, an ALD process so as to cover the inside of a trench formed by removing the polysilicon film (undoped polysilicon film) of the control gate electrode CG. A titanium nitride (TiN) film to be the Vth control metal film VM is formed to a thickness of about 2 to 3 nm by, for example, a PVD process directly over the High-k film HK. Subsequently, a metal layer (metal film MF3) of tungsten (W) or the like is formed over the semiconductor substrate SB to fill the trench by, for example, a PVD process, and planarization is performed by CMP polishing so as to leave the metal layer in the memory cell MC, and thus the metal gate electrode is formed.

Subsequently, as shown in FIG. 63, the buried tungsten (W) of the control gate electrode CG is partially etched by wet etching using, for example, APM (mixture of ammonia water (NH₄OH) and hydrogen peroxide solution (H₂O₂)) to form a recess of about 5 to 20 nm in the upper part of the control gate electrode CG.

A yield rate of the semiconductor device is expectably improved by the wet etching. For example, a metal residue (for example, CMP residue), causing a defect (for example, short-circuit) that may occur in the surface of the semiconductor substrate SB during formation of the metal gate electrode, is oxidized to lose conductivity, making it possible to prevent occurrence of defects.

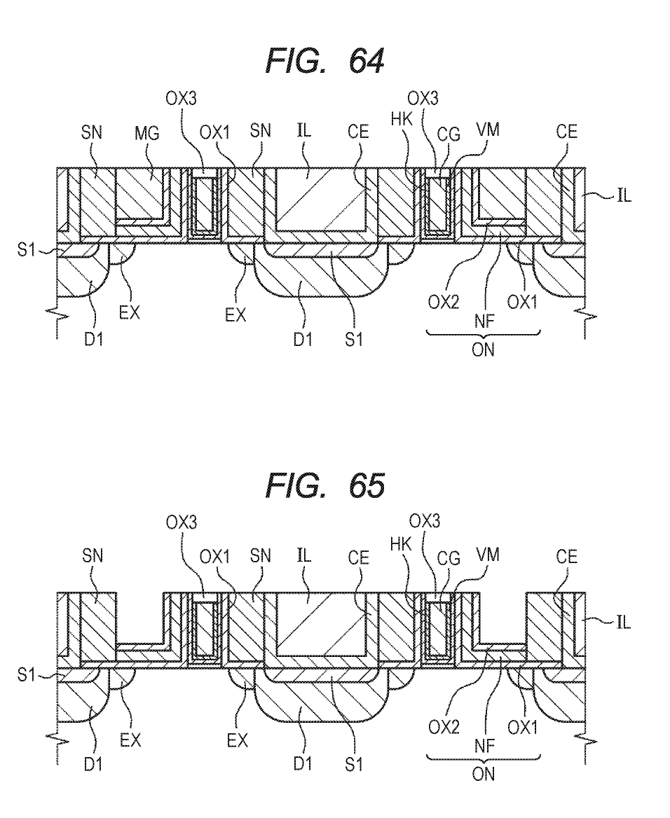

Subsequently, as shown in FIG. 64, a silicon oxide film (for example, a P-TEOS oxide film or an O₃-TEOS oxide film) is formed over the semiconductor substrate SB by a CVD process, and then the recess in the upper part of the control gate electrode CG is filled with a silicon oxide film OX3 by CMP polishing, so that the upper part of the control gate electrode CG is covered with the silicon oxide film OX3. At this time, a recess, which corresponds to a mark of the metal residue (for example, CMP residue) removed by the wet etching, is also filled with the silicon oxide film OX3 and thus planarization is achieved.

Subsequently, as shown in FIG. 65, the p-type polysilicon film of the memory gate electrode MG is removed by etching. Since the etching is performed to etch the p-type polysilicon, isotropic dry etching (using Cl₂ gas or HBr gas, for example) is performed instead of wet etching. At this time, the surface of the control gate electrode CG is protected by the silicon oxide film OX3 (for example, a P-TEOS oxide film or an O₃-TEOS oxide film).

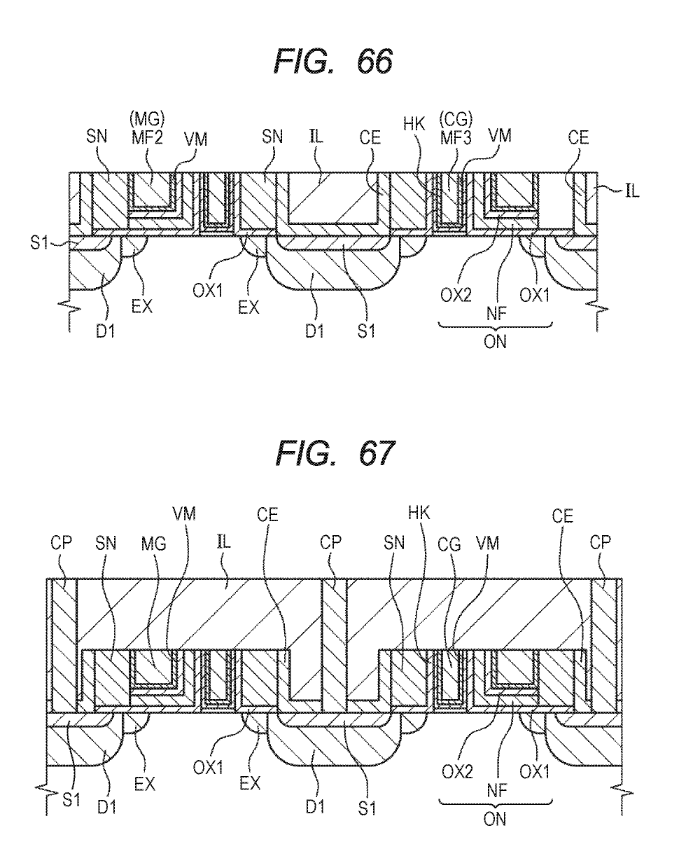

Subsequently, as shown in FIG. 66, a titanium nitride (TiN) film to be the Vth control metal film VM is formed to a thickness of about 2 to 3 nm by, for example, a PVD process directly over the ONO film ON (or AHA film) so as to cover the inside of a trench formed by removing the p-type polysilicon film of the memory gate electrode MG. Subsequently, a metal layer (metal film MF2) of aluminum (Al) or the like is formed over the semiconductor substrate SB to fill the trench by, for example, a PVD process, and planarization is performed by CMP polishing so as to leave the metal layer in the memory cell MC, and thus the metal gate electrode is formed.

Subsequently, as shown in FIG. 67, an interlayer insulating film IL including a P-TEOS oxide film or an O₃-TEOS oxide film is formed over the semiconductor substrate SB by a CVD process, for example. Subsequently, contact holes are formed by photolithography and dry etching. A conductive contact plug (via) CP made of tungsten (W) or the like is formed as a coupling conductor part in each contact hole by a CVD process and CMP polishing, for example. Subsequently, an interconnection MW (W interconnection, Al interconnection, or Cu interconnection) as shown in FIGS. 3A to 3C is formed by photolithography and dry etching or by an interconnect damascene technique.

The memory cell structure of the semiconductor device (SG-MONOS) of the fourth example is completed through the above-described manufacturing method.

Although the invention achieved by the inventors has been described in detail according to the embodiments hereinbefore, the invention should not be limited thereto, and it will be appreciated that various modifications or alterations thereof may be made within the scope without departing from the gist of the invention.

This application further has features according to supplementary notes 1 to 20.

### Supplementary Note 1

A method of manufacturing a semiconductor device, the method includes the steps of:

(a) forming a first gate electrode on a main surface of a semiconductor substrate via a first gate insulating film having a charge storage part;

(b) forming a second gate electrode adjacent to the first gate electrode via an insulating film and on the main surface of the semiconductor substrate via a second gate insulating film;

(c) forming an interlayer insulating film on the main surface of the semiconductor substrate so as to cover the first gate electrode and the second gate electrode;

(d) after the step (c), exposing the first gate electrode and the second gate electrode;

(e) removing the second gate electrode, and forming a first trench;

(f) after the step (e), forming a third gate electrode inside the first trench via a third gate insulating film;

(g) after the step (f), forming a recess in an upper part of the third gate electrode;

(h) after the step (g), forming a protective film on an upper surface of the third gate electrode so as to fill the recess;

(i) after the step (h), removing the first gate electrode to form a second trench; and

(j) after the step (i), forming a fourth gate electrode inside the second trench via the first gate insulating film.

### Supplementary Note 2

In the method according to supplementary note 1, the first gate electrode is a doped polysilicon electrode made of doped polysilicon containing a p-type impurity, and the second gate electrode is an undoped polysilicon electrode made of undoped polysilicon.

### Supplementary Note 3

In the method according to supplementary note 2, in the step (e), the second gate electrode is selectively removed by ammonia water or a mixture of ammonia water and hydrogen peroxide solution.

### Supplementary Note 4

In the method according to supplementary note 2in the step (i), the first gate electrode is selectively removed by dry etching using an etching gas including chlorine gas or hydrogen bromide gas.

### Supplementary Note 5

In the method according to supplementary note 1, the third gate insulating film is a High-K insulating film including a high dielectric constant film, the third gate electrode is a metal gate electrode made of tungsten, and the protective film formed in the step (h) is a silicon oxide film.

### Supplementary Note 6

In the method according to supplementary note 5, in the step (g), an upper part of the third gate electrode is selectively etched by a mixture of ammonia water and hydrogen peroxide solution.

### Supplementary Note 7

In the method according to supplementary note 1, the recess formed in the step (g) has a depth of 5 to 20 nm.

### Supplementary Note 8

In the method according to supplementary note 1, the first gate insulating film is an ONO film including a stacked film of a silicon oxide film, a silicon nitride film, and a silicon oxide film, and the fourth gate electrode is a metal gate electrode made of aluminum.

### Supplementary Note 9

In the method according to supplementary note 1, a titanium nitride film to be a Vth control metal film is formed between the third gate insulating film and the third gate electrode, and between the first gate insulating film and the fourth gate electrode.

### Supplementary Note 10

In the method according to supplementary note 1, a projecting semiconductor layer as part of the semiconductor substrate is provided in the main surface of the semiconductor substrate, the projecting semiconductor layer projecting from the main surface of the semiconductor substrate and extending along the main surface, and the first gate electrode, the second gate electrode, the third gate electrode, and the fourth gate electrode are each formed over the upper surface of the projecting semiconductor layer.

### Supplementary Note 11

A method of manufacturing a semiconductor device, includes the steps of:

(a) forming a first gate electrode on a main surface of a semiconductor substrate via a first gate insulating film;

(b) forming a second gate electrode adjacent to the first gate electrode via a second insulating film having a charge storage part and on the main surface of the semiconductor substrate via the second gate insulating film;

(c) forming an interlayer insulating film on the main surface of the semiconductor substrate so as to cover the first gate electrode and the second gate electrode;

(d) after the step (c), exposing the first gate electrode and the second gate electrode;

(e) removing the first gate electrode to form a first trench;

(f) after the step (e), forming a third gate electrode inside the first trench via a third gate insulating film;

(g) after the step (f), forming a recess in an upper part of the third gate electrode;

(h) after the step (g), forming a protective film on an upper surface of the third gate electrode so as to fill the recess;

(i) after the step (h), removing the second gate electrode, and forming a second trench; and

(j) after the step (i), forming a fourth gate electrode inside the second trench while the second gate insulating film is provided under the fourth gate electrode.

### Supplementary Note 12

In the method according to supplementary note 11, the first gate electrode is an undoped polysilicon electrode made of undoped polysilicon, and the second gate electrode is a doped polysilicon electrode made of doped polysilicon containing a p-type impurity.

### Supplementary Note 13

In the method according to supplementary note 12, in the step (e), the first gate electrode is selectively removed by ammonia water or a mixture of ammonia water and hydrogen peroxide solution.

### Supplementary Note 14

In the method according to supplementary note 12, in the step (i), the second gate electrode is selectively removed by dry etching using an etching gas including chlorine gas or hydrogen bromide gas.

### Supplementary Note 15

In the method according to supplementary note 11, the third gate insulating film is a High-K insulating film including a high dielectric constant film, the third gate electrode is a metal gate electrode made of tungsten, and the protective film formed in the step (h) is a silicon oxide film.

### Supplementary Note 16

In the method according to supplementary note 15, in the step (g), the upper part of the third gate electrode is selectively etched by a mixture of ammonia water and hydrogen peroxide solution.

### Supplementary Note 17

In the method according to supplementary note 11, the recess formed in the step (g) has a depth of 5 to 20 nm.

### Supplementary Note 18

In the method according to supplementary note 11, the second gate insulating film is an ONO film including a stacked film of a silicon oxide film, a silicon nitride film, and a silicon oxide film, and the fourth gate electrode is a metal gate electrode made of aluminum.

### Supplementary Note 19

In the method according to supplementary note 11, a titanium nitride film to be a Vth control metal film is formed between the third gate insulating film and the third gate electrode, and between the second gate insulating film and the fourth gate electrode.

### Supplementary Note 20

In the method according to supplementary note 11, a projecting semiconductor layer as part of the semiconductor substrate is provided in the main surface of the semiconductor substrate, the projecting semiconductor layer projecting from the main surface of the semiconductor substrate and extending along the main surface, and the first gate electrode, the second gate electrode, the third gate electrode, and the fourth gate electrode are each formed over the upper surface of the projecting semiconductor layer.

What is claimed is:

1. A method of manufacturing a semiconductor device, comprising the steps of:
(a) forming a first gate electrode on a main surface of a semiconductor substrate via a first gate insulating film having a charge storage part;
(b) forming a second gate electrode adjacent to the first gate electrode via an insulating film and on the main surface of the semiconductor substrate via a second gate insulating film;
(c) forming an interlayer insulating film on the main surface of the semiconductor substrate so as to cover the first gate electrode and the second gate electrode;
(d) after the step (c), exposing the first gate electrode and the second gate electrode;
(e) removing the second gate electrode, and forming a first trench;
(f) after the step (e), forming a third gate electrode inside the first trench via a third gate insulating film;
(g) after the step (f), forming an oxidized layer in a surface of the third gate electrode;
(h) after the step (g), removing the first gate electrode, and forming a second trench; and
(i) after the step (h), forming a fourth gate electrode inside the second trench.

2. The method according to claim 1,
wherein the first gate electrode is a doped polysilicon electrode made of doped polysilicon containing a p-type impurity; and
wherein the second gate electrode is an undoped polysilicon electrode made of undoped polysilicon.

3. The method according to claim 2, wherein in the step (e), the second gate electrode is selectively removed by ammonia water or a mixture of ammonia water and hydrogen peroxide solution.

4. The method according to claim 2, wherein in the step (h), the first gate electrode is selectively removed by dry etching using an etching gas including chlorine gas or hydrogen bromide gas.

5. The method according to claim 1,
wherein the third gate insulating film is a High-K insulating film including a high dielectric constant film,
wherein the third gate electrode is a metal gate electrode made of aluminum, and
wherein the oxidized layer formed in the step (g) is an aluminum oxide layer.

6. The method according to claim 5, wherein the surface oxidation treatment in the step (g) is low-temperature oxidation or plasma oxidation performed at a temperature of 400° C. or lower.

7. The method according to claim 5, wherein the aluminum oxide layer has a thickness of 5 to 20 nm.

8. The method according to claim 1,
wherein the first gate insulating film is an ONO film including a stacked film of a silicon oxide film, a silicon nitride film, and a silicon oxide film, and
wherein the fourth gate electrode is a metal gate electrode made of aluminum.

9. The method according to claim 1, wherein a titanium nitride film to be a Vth control metal film is formed between the third gate insulating film and the third gate electrode, and between the first gate insulating film and the fourth gate electrode.

10. The method according to claim 1,
wherein a projecting semiconductor layer as part of the semiconductor substrate is provided in the main surface of the semiconductor substrate, the projecting semiconductor layer projecting from the main surface of the semiconductor substrate and extending along the main surface, and
wherein the first gate electrode, the second gate electrode, the third gate electrode, and the fourth gate electrode are each formed over the upper surface of the projecting semiconductor layer.

11. A method of manufacturing a semiconductor device, comprising the steps of:
(a) forming a first gate electrode on a main surface of a semiconductor substrate via a first gate insulating film;
(b) forming a second gate electrode adjacent to the first gate electrode via a second insulating film having a charge storage part and on the main surface of the semiconductor substrate via the second gate insulating film;
(c) forming an interlayer insulating film on the main surface of the semiconductor substrate so as to cover the first gate electrode and the second gate electrode;
(d) after the step (c), exposing the first gate electrode and the second gate electrode;
(e) removing the first gate electrode and forming a first trench;
(f) after the step (e), forming a third gate electrode inside the first trench via a third gate insulating film;
(g) after the step (f), forming an oxidized layer in a surface of the third gate electrode;
(h) after the step (g), removing the second gate electrode to form a second trench; and
(i) after the step (h), forming a fourth gate electrode inside the second trench.

12. The method according to claim 11,
wherein the first gate electrode is an undoped polysilicon electrode made of undoped polysilicon; and
wherein the second gate electrode is a doped polysilicon electrode made of doped polysilicon containing a p-type impurity.

13. The method according to claim 12, wherein in the step (e), the first gate electrode is selectively removed by ammonia water or a mixture of ammonia water and hydrogen peroxide solution.

14. The method according to claim 12, wherein in the step (h), the second gate electrode is selectively removed by dry etching using an etching gas including chlorine gas or hydrogen bromide gas.

15. The method according to claim 11,
wherein the third gate insulating film is a High-K insulating film including a high dielectric constant film,
wherein the third gate electrode is a metal gate electrode made of aluminum, and
wherein the oxidized layer formed in the step (g) is an aluminum oxide layer.

16. The method according to claim 15, wherein the surface oxidation treatment in the step (g) is low-temperature oxidation or plasma oxidation performed at a temperature of 400° C. or lower.

17. The method according to claim 15, wherein the aluminum oxide layer has a thickness of 5 to 20 nm.

18. The method according to claim 11,
wherein the second gate insulating film is an ONO film including a stacked film of a silicon oxide film, a silicon nitride film, and a silicon oxide film, and
wherein the fourth gate electrode is a metal gate electrode made of aluminum.

19. The method according to claim 11, wherein a titanium nitride film to be a Vth control metal film is formed between the third gate insulating film and the third gate electrode, and between the second gate insulating film and the fourth gate electrode.

20. The method according to claim 11,
wherein a projecting semiconductor layer as part of the semiconductor substrate is provided in the main surface of the semiconductor substrate, the projecting semiconductor layer projecting from the main surface of the semiconductor substrate and extending along the main surface, and
wherein the first gate electrode, the second gate electrode, the third gate electrode, and the fourth gate electrode are each formed over the upper surface of the projecting semiconductor layer.
